(19) United States
(12) Patent Application Publication
(10) Pub. No.: US 2026/0080127 A1
(43) Pub. Date: Mar. 19, 2026

(54) GENERATIVE CONSTRAINING AND DIMENSIONING OF COMPUTER-AIDED DESIGN SKETCHES

(71) Applicant: AUTODESK, INC., San Francisco, CA (US)

(72) Inventors: Karl D. D. WILLIS, San Francisco, CA (US); Mor KATZ, Lafayette, CA (US); Joseph George LAMBOURNE, London (GB); Walker Evan CASEY, Porto (PT); Pradeep Kumar JAYARAMAN, Toronto (CA); Tianyu ZHANG, Edmonton (CA); John Roger THOMPSON, Atlanta, GA (US); Shu ISHIDA, London (GB); Amir Hosein KHAS AHMADI, Toronto (CA)

(21) Appl. No.: 19/301,729

(22) Filed: Aug. 15, 2025

Related U.S. Application Data
(60) Provisional application No. 63/696,791, filed on Sep. 19, 2024.
(60) Provisional application No. 63/771,560, filed on Mar. 13, 2025.

(51) Int. Cl. G06F 30/27

(52) U.S. Cl. CPC G06F 30/27

(57) ABSTRACT

Generative constraining and dimensioning of CAD sketches includes receiving training data comprising a plurality of training data elements, each training data element comprising an input sketch and a ground truth constraint sequence, selecting a first training data element from the plurality of training data elements, generating a variable length prompt from the first training data element, presenting the variable length prompt to a constraint generation model to generate a first constraint sequence, generating a loss based on the first constraint sequence, and updating the constraint generation model based on the loss.

### CROSS-REFERENCE TO RELATED APPLICATIONS

The present application claims the benefit of U.S. Provisional Application titled, “TECHNIQUES FOR ALIGNING CONSTRAINT GENERATION WITH DESIGN INTENT IN PARAMETRIC CAD MODELING,” filed on Mar. 13, 2025, and having Ser. No. 63/771,560 and U.S. Provisional Application titled, “TECHNIQUES FOR GENERATIVE CONSTRAINING AND DIMENSIONING OF COMPUTER-AIDED DESIGN SKETCHES,” filed on Sep. 19, 2024, and having Ser. No. 63/696,791. The subject matter of these related application is hereby incorporated herein by reference.

### BACKGROUND

### Field of the Various Embodiments

Embodiments of the present disclosure relate generally to computer science, artificial intelligence, and machine learning, and, more specifically, to generative constraining and dimensioning of computer-aided design sketches.

### Description of the Related Art

Parametric computer-aided design (CAD) software often provides tools for constraining two-dimensional or three-dimensional drawings or sketches and assigning dimensions such as linear or angular measurements. A constraint can include a set of rules or conditions that govern geometric relationships (e.g., perpendicularity between lines) of a specific drawing. Traditional constraint solvers employ techniques such as heuristic techniques that apply rules of thumb (e.g., add constraints for geometry that appears obviously parallel or perpendicular) to lines or curves or a partial ordering (e.g., always constrain the largest circle) to limit the search space in the drawing.

Some conventional constraint solver techniques insert every identifiable constraint or dimension, resulting in over-constrained conditions or solver failures. Such conditions impede editing of CAD drawings, often forcing manual removal or overriding of one or more of the constraints. Other solver techniques rely on guesswork to decide which constraints are needed, leading to unpredictable or incomplete constraint sets that fail to lock down essential geometric features such as the lengths of an arch or the positions of pivot points.

Traditional machine learning models, such as transformers and other autoregressive architectures have shown some promise at generating constraints. These machine learning techniques receive a CAD drawing as input and encode the geometric features into a vector. A decoder then unfolds the vector into a sequence of constraint statements (e.g., coincident, parallel) or into a parameter set that is later reassembled into constraint equations. These machine learning models can often capture dependencies between distant geometric features.

A drawback of these machine learning techniques is that the machine learning models are not adequately trained to address the complexities of training data. For example, training data limitations, including hidden correlations, unlabeled feature variants, and coverage gaps require additional supervision or post-processing for correction, and are not well-learned by these machine learning models. In particular, some of the machine learning models rely on constrained or sparsely labeled training examples, limiting the ability of the machine learning models to learn geometric relationships or capture design preferences. When the machine learning models are trained on incomplete or inconsistent datasets, incorrect or misaligned constraints can be generated, causing over-constrained, under-constrained, or contradictory constraints.

As the foregoing illustrates, what is needed in the art are more effective techniques for generative constraining and dimensioning of CAD sketches.

### SUMMARY

According to some embodiments, a computer-implemented method for training a constraint generation model comprises receiving training data comprising a plurality of training data elements, each training data element comprising an input sketch and a ground truth constraint sequence, selecting a first training data element from the plurality of training data elements, generating a variable length prompt from the first training data element, presenting the variable length prompt to a constraint generation model to generate a first constraint sequence, generating a loss based on the first constraint sequence, and updating the constraint generation model based on the loss.

Further embodiments provide, among other things, non-transitory computer-readable storage media storing instructions and systems configured to implement the method set forth above.

One technical advantage of the disclosed techniques relative to prior art is that the disclosed techniques more effectively capture complex geometric features and relationships of CAD sketches. The disclosed techniques also generate constraint sequences that are more accurate and more likely to converge and are more likely to result in fewer under-constrained, over-constrained, or contradictory constraints than constraint sequences generated by prior art techniques. The disclosed techniques further accelerate training convergence so that a constraint generation model can be trained using fewer training epochs and reduced computational resources. The disclosed techniques additionally support continual improvement to the constraint generation model. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a block diagram of a computer-based system, according to various embodiments;

FIG. 2 is a more detailed illustration of a computing device, configured to implement one or more aspects of the various embodiments;

FIG. 3 illustrates an architecture of the trained model of FIG. 1, according to various embodiments;

FIG. 4 is a more detailed illustration of the geometry embedding layer of FIG. 3, according to various embodiments;

FIG. 5 is a more detailed illustration of the SFT module of FIG. 1, according to various embodiments;

FIG. 6 is a more detailed illustration of the scoring module of FIG. 1, according to various embodiments;

FIG. 7 is a more detailed illustration of the preference-based optimization module of FIG. 1, according to various embodiments;

FIG. 8 is a more detailed illustration of the reinforcement learning module of FIG. 1, according to various embodiments;

FIG. 9 is a flow diagram of method steps for generating constraint sequences from an input sketch, according to various embodiments;

FIG. 10 is a flow diagram of method steps for supervised training and fine tuning of a constraint generation model, according to various embodiments;

FIG. 11A is a flow diagram of method steps for performing different alignment training techniques on a trained model, according to various embodiments;

FIG. 11B is a flow diagram of method steps for expert iteration, according to various embodiments;

FIG. 11C is a flow diagram of method steps for direct preference optimization, according to various embodiments;

FIG. 11D is a flow diagram of method steps for per constraint reinforcement learning, according to various embodiments; and

FIG. 11E is a flow diagram of method steps for per sequence reinforcement learning, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### System Overview

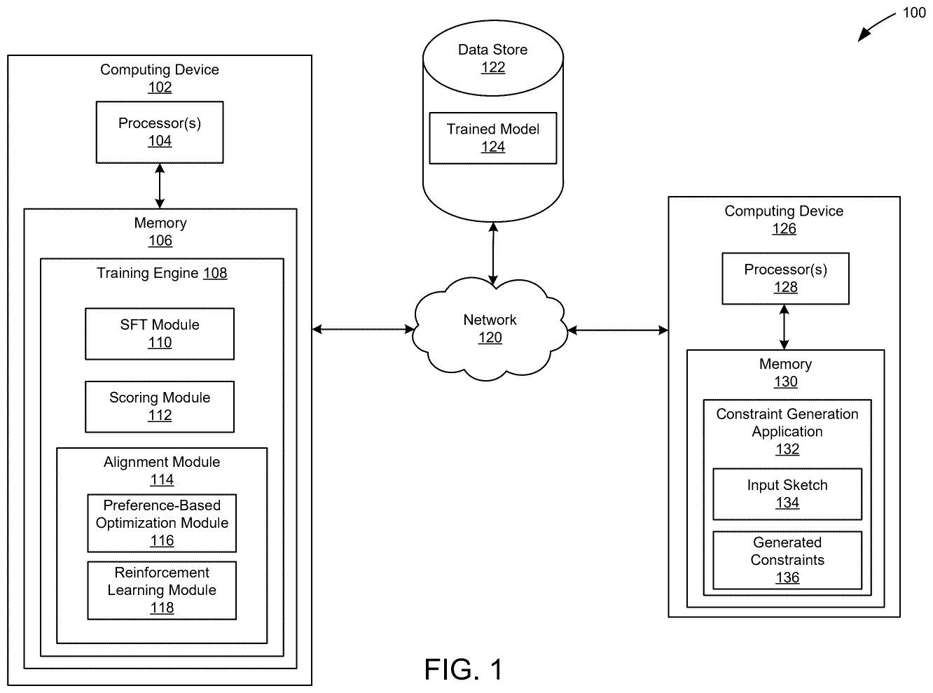

FIG. 1 is a block diagram of a computer-based system 100 that implements the disclosed techniques for constraint generation in CAD sketches. System 100 includes, without limitation, computing device 102, network 120, data store 122, and computing device 126. Computing device 102 includes, without limitation, one or more processors 104 and memory 106. Memory 106 includes, without limitation, a training engine 108. Training engine 108 includes, without limitation, a SFT module 110, a scoring module 112, and an alignment module 114. Alignment module 114 includes, without limitation, a preference-based optimization module 116 and a reinforcement learning module 118. Data store 122 includes, without limitation, a trained model 124. Computing device 126 includes, without limitation, one or more processors 128 and memory 130. Memory 130 includes, without limitation, a constraint generation application 132. Constraint generation application 132 includes, without limitation, an input sketch 134 and generated constraints 136.

Each of the one or more processors 104 can be any suitable processor, such as a central processing unit (CPU), a graphics processing unit (GPU), an application specific integrated circuits (ASICs), a field programmable gate arrays (FPGA), a digital signal processor (DSP), a multicore processor, and/or any other type of processing unit, or a combination of two or more of a same type and/or different types of processing units, such as a system-on-a-chip (SoC), or a CPU configured to operate in conjunction with a GPU. In general, processor(s) 104 can be any technically feasible hardware unit capable of processing data including training machine learning models.

Memory 106 of computing device 102 stores content, such as computer-executable instructions and data, for use by processor(s) 104. Memory 106 can be any type of memory capable of storing data and computer-executable instructions, such as a random-access memory (RAM), a read-only memory (ROM), an erasable programmable read-only memory (EPROM or Flash ROM), or any suitable combination of the foregoing. In some embodiments, additional storage (not shown) can supplement or replace memory 106. The storage can include any number and type of external memories that are accessible to processor(s) 104. For example, and without limitation, the storage can include a secure digital card, an external Flash memory, a portable CD-ROM, an optical storage device, a magnetic storage device, and/or any suitable combination of the foregoing.

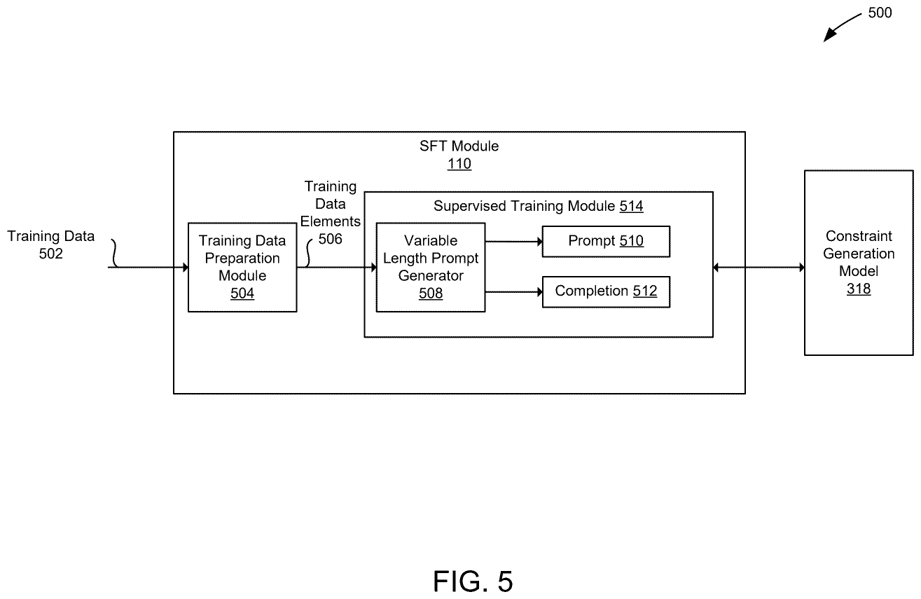

Training engine 108 trains a constraint generation model using SFT module 110, evaluates candidate constraint sequences generated by the constraint generation model using scoring module 112, and applies preference-based optimization module 116 and/or reinforcement learning module 118 using alignment module 114. SFT module 110 receives training data. Each piece of training data includes CAD drawings or sketches and ground truth constraint sequences. In some cases, a sketch can be partially or fully constrained and can include one or more constraints. The ground truth constraint sequences can be labeled by human designers or using a reference constraint solver. The training data can be loaded from data store 122, computing device 126, or another source (not shown). SFT module 110 then performs several preparation steps on the training data such as filtering and/or augmentation. SFT module 110 then trains the constraint generation model based on the prepared training data. SFT module 110 then performs additional training of the constraint generation model using high-quality training data. SFT module 110 is described in further detail in FIG. 5.

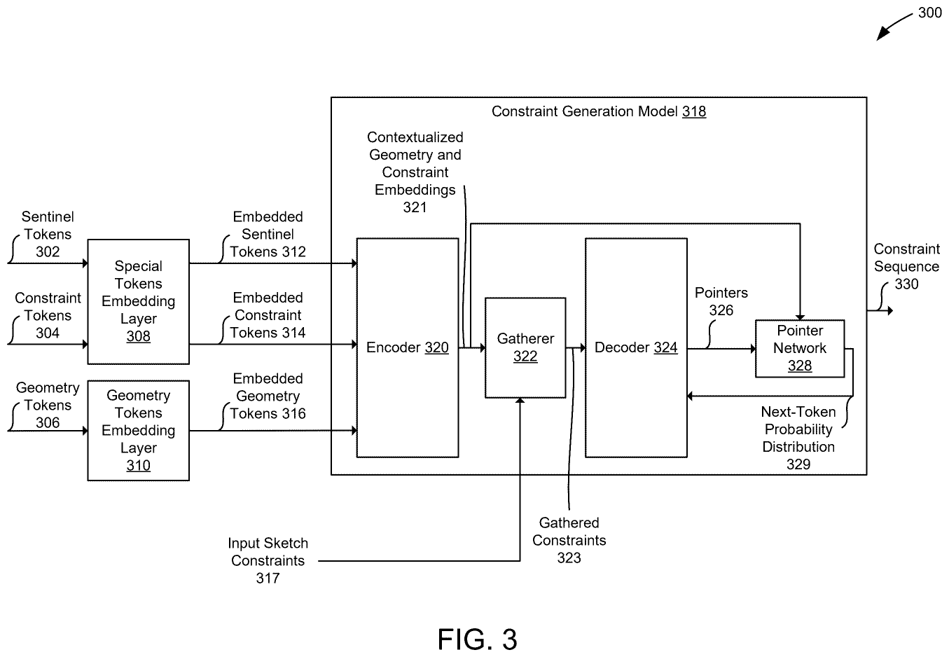

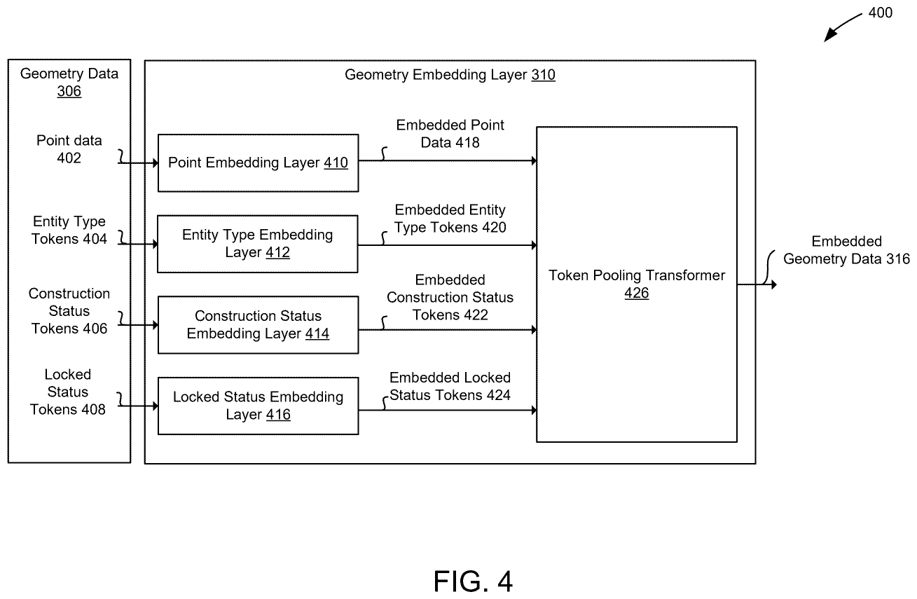

The constraint generation model is a tokenization and embedding based architecture that includes an encoder, a pointer network-equipped transformer decoder, and associated token embeddings. The constraint generation model is described in further detail in FIGS. 3 and 4.

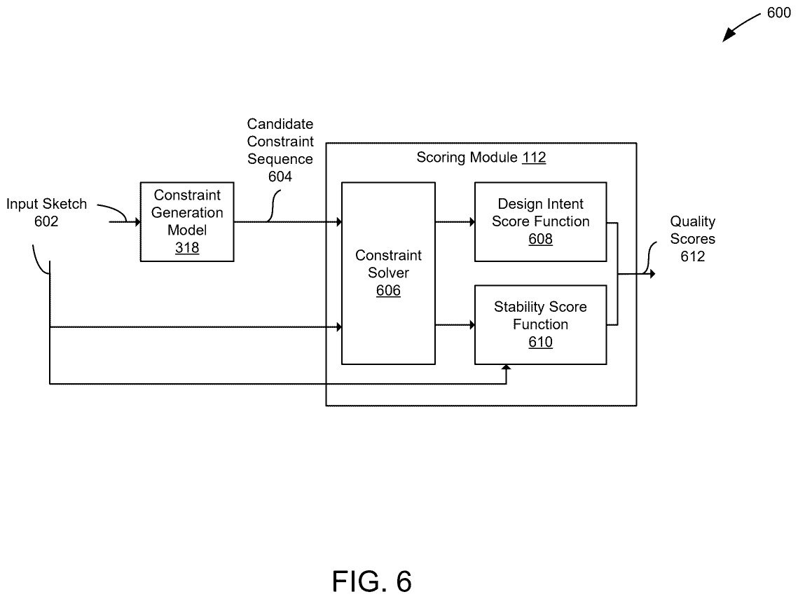

Scoring module 112 evaluates candidate constraint sequences generated by the constraint generation model trained by training engine 108. Scoring module 112 receives as input an input sketch and a candidate constraint sequence generated by the constraint generation model from the input sketch. Scoring module 112 evaluates the input sketch and the candidate constraint sequence to generate one or more quality scores. Scoring module 112 is described in further detail in FIG. 6.

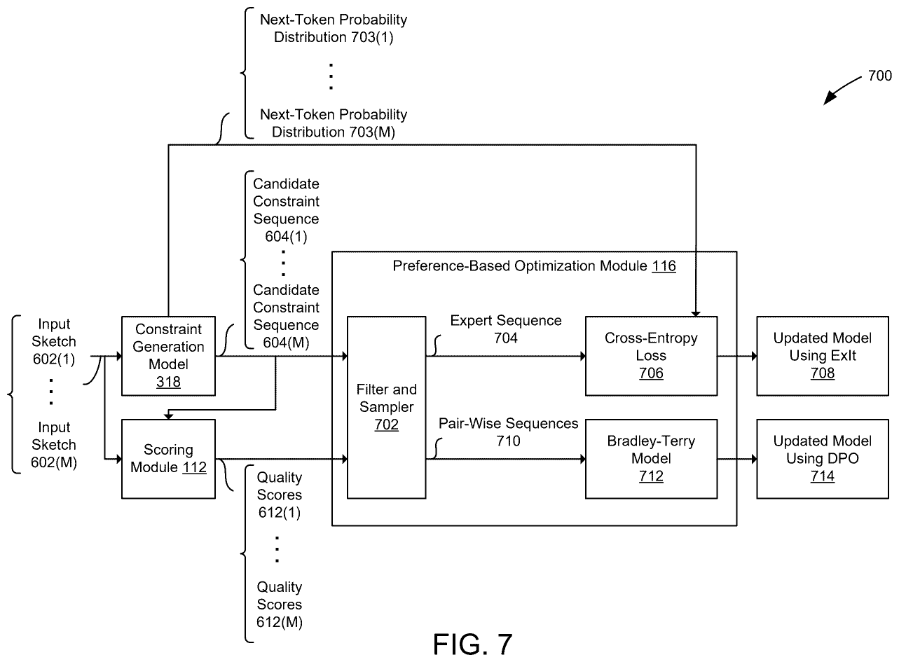

Alignment module 114 applies machine learning alignment techniques including preference-based optimization module 116 and/or reinforcement learning module 118 to iteratively update the constraint generation model. Preference-based optimization module 116 performs expert iteration (ExIt) optimization and/or direct preference optimization (DPO) to update the constraint generation model. ExIt filters or ranks constraint sequences using the quality scores from scoring module 112. Then, ExIt uses a cross-entropy loss to update the SFT module 110 trained constraint generation model. The updated SFT module 110 trained constraint generation model is then stored as trained model 124. DPO samples constraint sequences and forms ranked pairs of constraint sequences. Next, DPO rewards each pair with the Bradley-Terry model to translate each ranking into a preference-loss term and applies penalty that discourages large changes to the SFT module 110 trained constraint generation model. DPO updates the SFT module 110 trained constraint generation model using the rewards and penalties. The updated SFT module 110 trained constraint generation model is stored in trained model 124. Preference-based optimization module 116 is described in further detail in FIG. 7.

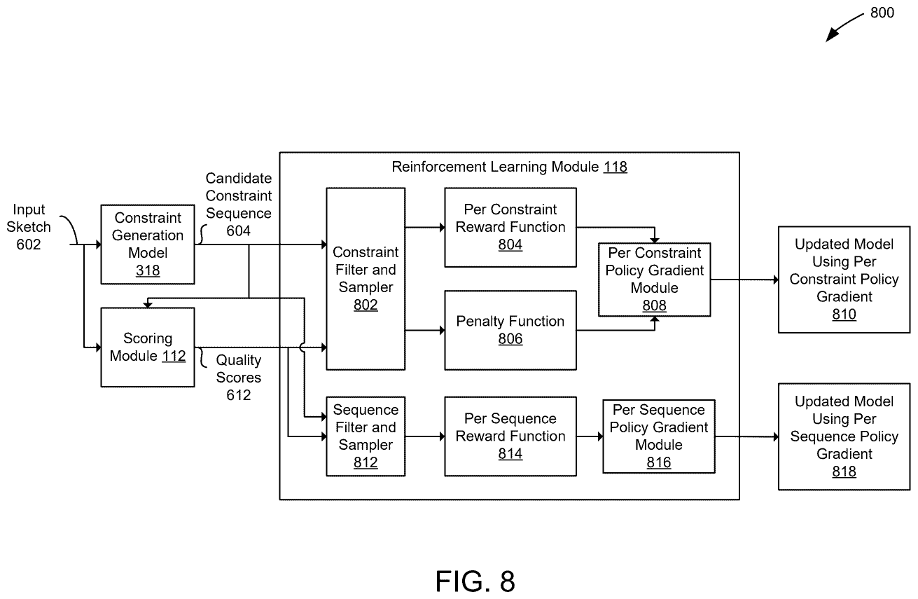

Reinforcement learning module 118 applies one or more alignment techniques to the trained constraint generation model. Reinforcement learning module 118 samples constraints or constraint sequences generated by the trained constraint generation model, assigns rewards that favor fully constrained or low-DOF sketches and penalize over constrained sketches, unsolvable sketches, or unstable sketches. The reinforcement learning then uses the rewards and/or penalties to generate a policy-gradient and applies the policy-gradient to update the SFT module 110 trained constraint generation model. The updated constraint generation model is stored as trained model 124 in data store 122. Reinforcement learning module 118 is described in further detail in FIG. 8.

Network 120 represents any technically feasible communication fabric, including but not limited to the Internet, a wide-area network (WAN), a local-area network (LAN), a cellular network, or a combination thereof. Network 120 enables bidirectional data flow among computing device 102, data store 122, and computing device 126, including transmission of constraint generation model, training data, and input sketch.

Data store 122 includes any combination of fixed-disk drives, solid-state drives, network-attached storage, or cloud-based object storage capable of persistently storing constraint generation model and training data. Data store 122 stores trained model 124. Trained model 124 is the latest update of the constraint generation model generated by training engine 108. Trained model 124 includes an encoder, a pointer network-equipped transformer decoder, and associated token embeddings.

Each of processor(s) 128 can be any suitable processor, such as a central processing unit (CPU), a graphics processing unit (GPU), an application specific integrated circuits (ASICs), a field programmable gate arrays (FPGA), a digital signal processor (DSP), a multicore processor, and/or any other type of processing unit, or a combination of two or more of a same type and/or different types of processing units, such as a system-on-a-chip (SoC), or a CPU configured to operate in conjunction with a GPU. In general, processors 104 can be any technically feasible hardware unit capable of processing data including executing software applications.

Memory 130 stores constraint generation application 132. Memory 130 of computing device 126 stores content, such as computer-executable instructions and data, for use by processor(s) 128. Memory 130 can be any type of memory capable of storing data and computer-executable instructions, such as a random-access memory (RAM), a read-only memory (ROM), an erasable programmable read-only memory (EPROM or Flash ROM), or any suitable combination of the foregoing. In some embodiments, additional storage (not shown) can supplement or replace memory 130. The storage can include any number and type of external memories that are accessible to processor(s) 128. For example, and without limitation, the storage can include a secure digital card, an external Flash memory, a portable CD-ROM, an optical storage device, a magnetic storage device, and/or any suitable combination of the foregoing.

Constraint generation application 132 receives input sketch 134 and uses trained model 124 to generate generated constraints 136. Input sketch 134 is a CAD drawing or sketch received from a user or generated by a CAD module. In some instances, input sketch 134 includes one or more constraints. Constraint generation application 132 provides input sketch 134 to trained model 124. Trained model 124 tokenizes the geometry and relevant special tokens for input sketch 134 and then autoregressively generates generated constraints 136. Constraint generation application 132 then provides generated constraints 136 to a user or saves generated constraints 136.

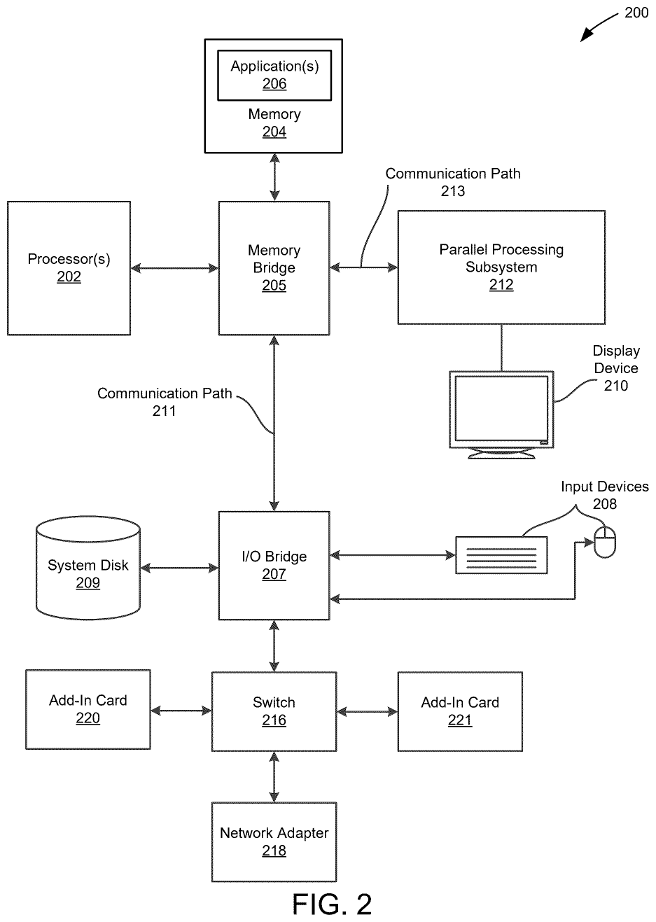

FIG. 2 is a more detailed illustration of a computing device 200, configured to implement one or more aspects of the various embodiments. In some embodiments, computing devices 102 and/or 126 are implemented using computing device 200. Computing device 200 can include any type of computing system, including, without limitation, a server machine, a server platform, a desktop machine, a laptop machine, a hand-held/mobile device, a digital kiosk, an in-vehicle infotainment system, and/or a wearable device. In some embodiments, the computing device 200 is a server machine operating in a data center or a cloud computing environment that provides scalable computing resources as a service over a network.

As shown, the computing device 200 includes, without limitation, processor(s) 202 and memory 204 coupled to a parallel processing subsystem 212 via a memory bridge 205 and a communication path 213. The memory bridge 205 is further coupled to an I/O (input/output) bridge 207 via a communication path 211, and the I/O bridge 207 is, in turn, coupled to a switch 216. Memory 204 includes, without limitation, one or more applications 206. For example, the one or more applications 206 could include training engine 108 and/or constraint generation application 132.

In some embodiments, the I/O bridge 207 is configured to receive user input information from optional input devices 208, such as a keyboard, mouse, touch screen, sensor data analysis (e.g., evaluating gestures, speech, or other information about one or more uses in a field of view or sensory field of one or more sensors), and/or the like, and forward the input information to the processor(s) 202 for processing. In some embodiments, the computing device 200 is a server machine in a cloud computing environment. In such embodiments, the computing device 200 does not include input devices 208, but can receive equivalent input information by receiving commands (e.g., responsive to one or more inputs from a remote computing device) in the form of messages transmitted over a network and received via the network adapter 218. In some embodiments, the switch 216 is configured to provide connections between the I/O bridge 207 and other components of the computing device 200, such as a network adapter 218 and various add-in cards 220 and 221.

In some embodiments, the I/O bridge 207 is coupled to a system disk 209 that can be configured to store content and applications and data for use by processor(s) 202 and the parallel processing subsystem 212. In some embodiments, the system disk 209 provides non-volatile storage for applications and data and can include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid state storage devices. In various embodiments, other components, such as universal serial bus or other port connections, compact disc drives, digital versatile disc drives, film recording devices, and the like, can be connected to the I/O bridge 207 as well.

In various embodiments, the memory bridge 205 is a Northbridge chip, and the I/O bridge 207 is a Southbridge chip. In addition, the communication paths 211 and 213, as well as other communication paths within the computing device 200, can be implemented using any technically suitable protocols, including, without limitation, AGP (Accelerated Graphics Port), HyperTransport, or any other bus or point-to-point communication protocol known in the art.

In some embodiments, the parallel processing subsystem 212 comprises a graphics subsystem that delivers pixels to an optional display device 210 that can be any conventional cathode ray tube, liquid crystal display, light-emitting diode display, and/or the like. In such embodiments, the parallel processing subsystem 212 can incorporate circuitry optimized for graphics and video processing, including, for example, video output circuitry. Such circuitry can be incorporated across one or more parallel processing units (PPUs), also referred to herein as parallel processors, included within the parallel processing subsystem 212.

In some embodiments, the parallel processing subsystem 212 incorporates circuitry optimized (e.g., that undergoes optimization) for general purpose and/or compute processing. Again, such circuitry can be incorporated across one or more PPUs included within the parallel processing subsystem 212 that are configured to perform such general purpose and/or compute operations. In yet other embodiments, the one or more PPUs included within the parallel processing subsystem 212 can be configured to perform graphics processing, general purpose processing, and/or compute processing operations. The memory 204 includes at least one device driver configured to manage the processing operations of the one or more PPUs within the parallel processing subsystem 212. In addition, the memory 204 includes the application(s) 206. Although described herein primarily with respect to the application(s) 206, techniques disclosed herein can also be implemented, either entirely or in part, in other software and/or hardware, such as in the parallel processing subsystem 212.

In various embodiments, the parallel processing subsystem 212 can be integrated with one or more of the other elements of FIG. 2 to form a single system. For example, the parallel processing subsystem 212 can be integrated with the processor(s) 202 and other connection circuitry on a single chip to form a system on a chip (SoC).

In some embodiments, the processor(s) 202 includes the primary processor of application(s) 206, controlling and coordinating operations of other system components. In some embodiments, the processor(s) 202 issue commands that control the operation of PPUs. In some embodiments, the communication path 213 is a PCI Express link, in which dedicated lanes are allocated to each PPU. Other communication paths can also be used. The PPU advantageously implements a highly parallel processing architecture, and the PPU can be provided with any amount of local parallel processing memory (PP memory).

It will be appreciated that the system shown herein is illustrative and that variations and modifications are possible. The connection topology, including the number and arrangement of bridges, the number of processor(s) 202, and the number of parallel processing subsystems 212, can be modified as desired. For example, in some embodiments, the memory 204 could be connected to the processor(s) 202 directly rather than through the memory bridge 205, and other devices can communicate with the memory 204 via the memory bridge 205 and the processor(s) 202. In other embodiments, the parallel processing subsystem 212 can be connected to the I/O bridge 207 or directly to the processor(s) 202, rather than to the memory bridge 205. In still other embodiments, the I/O bridge 207 and the memory bridge 205 can be integrated into a single chip instead of existing as one or more discrete devices. In certain embodiments, one or more components shown in FIG. 2 are not present. For example, the switch 216 could be eliminated, and the network adapter 218 and the add-in cards 220, 221 would connect directly to the I/O bridge 207. Lastly, in certain embodiments, one or more components shown in FIG. 2 are implemented as virtualized resources in a virtual computing environment, such as a cloud computing environment. For example, the parallel processing subsystem 212 can be implemented as a virtualized parallel processing subsystem in at least one embodiment. As a specific example, the parallel processing subsystem 212 can be implemented as virtual graphics processing unit(s) (vGPU(s)) that render graphics on a virtual machine(s) (VM(s)) executing on server machine(s) whose GPU(s) and other physical resources are shared across one or more VMs.

### Constraint Generation Model

FIG. 3 illustrates an architecture 300 of trained model 124, according to various embodiments. As shown, architecture 300 includes, without limitation, a special tokens embedding layer 308, a geometry embedding layer 310, and a constraint generation model 318. Constraint generation model 318 includes, without limitation, an encoder 320, a gatherer 322, a decoder 324, and a pointer network 328. In operation, special tokens embedding layer 308 generates embedded sentinel tokens 312 from sentinel tokens 302. Special tokens embedding layer 308 further generates embedded constraint tokens 314 from constraint tokens 304. Geometry embedding layer 310 generates embedded geometry data 316 from geometry data 306. Encoder 320 uses embedded sentinel tokens 312, embedded constraint tokens 314, and embedded geometry data 316 to generate contextualized geometry and constraint embeddings 321. Gatherer 322 processes contextualized geometry and constraint embeddings 321 and input sketch constraints 317 to generate gathered constraints 323. Decoder 324 uses gathered constraints 323 and next-token probability distribution 329 to generate pointers 326. Pointer network 328 uses pointers 326 and contextualized geometry and constraint embeddings 321 to generate a next-token probability distribution 329.

Sentinel tokens 302 represent control symbols that include, without limitation, a start-of-sequence token <SOS>, an end-of-prompt token <EOP>, a padding token <PAD>, an end-of-sequence token <EOS>. Sentinel tokens 302 instruct the constraint generation model 318 for example, when a prompt ends, or when constraint generation should end.

Constraint tokens 304 represent the geometric relationships found in an input sketch to be processed by constraint generation model 318. Each token in constraint tokens 304 corresponds to a geometric relationship between geometric entities in the input sketch. The geometric entities include, without limitation, points, lines, arcs, circles, polygons, or composite curves. For example, the geometric relationships include such relationships as <PARALLEL>, <PERPENDICULAR>, <TANGENT>, <HORIZONTAL>, and/or the like. The geometric relationships could also include dimension types, such as <LINEAR-DIMENSION> and/or the like of a geometric entity in the input sketch. In some examples, a constraint token in constraint tokens 304 references one or more of the geometric entities in the input sketch using an index or pointer. Constraint tokens 304 are generated by tokenizing any constraint associated with an input sketch to be processed by constraint generation model 318. In some embodiments, the input sketch is received from data store 122, or computing device 126.

Geometry data 306 represent the types (e.g., points, lines, arcs, circles, or the like) of the geometric entities in the input sketch. In addition, geometry data 306 include, without limitation, point data, construction status tokens and locked status tokens. Each point data represents the coordinates (e.g., Cartesian coordinates) of some portion of a geometric entity in the input sketch. Each construction status token represents whether a geometric entity in the input sketch is construction geometry that provides reference or aid to apply constraints to the input sketch. For example, lines and other indicia that provide additional detail on the geometric entities in the input sketch but are not actually part of the geometry of the one or more objects depicted in the input sketch. Each locked status token represents whether a geometric entity is linked or fixed. A linked geometry includes a geometric entity that is associated with another source sketch. A fixed geometry includes a geometric entity that is locked in position (e.g., a fixed line). Geometry data 306 are generated by tokenizing the geometry of the geometric entities in the input sketch to be processed by constraint generation model 318. Geometry data 306 are described in further detail in FIG. 4.

Special tokens embedding layer 308 receives the sentinel tokens 302 and the constraint tokens 304. Special tokens embedding layer 308 encodes sentinel tokens 302 using a learned embedding table (e.g., PyTorch learned table torch.nn. Embedding). The embedded sentinel tokens are then concatenated into a vector as embedded sentinel tokens 312. Special tokens embedding layer 308 also encodes constraint tokens 304 using a learned embedding table (e.g., PyTorch learned table torch.nn. Embedding). The embedded constraint tokens are then concatenated into a vector as embedded constraint tokens 314.

Geometry embedding layer 310 receives geometry data 306 and generates embedded geometry data 316. Geometry embedding layer 310 uses a transformer to embed geometry data 306. The embedded geometry data are then concatenated into a vector as embedded geometry data 316. Geometry embedding layer 310 is described in further detail in FIG. 4.

Encoder 320 within constraint generation model 318 includes a bi-directional transformer that receives embedded sentinel tokens 312, embedded constraint tokens 314, and embedded geometry data 316. Constraint generation model 318 concatenates embedded sentinel tokens 312, embedded constraint tokens 314, and embedded geometry data 316 to generate a concatenated sequence. Next, encoder 320 processes the concatenated sequence using a multi-head self-attention network. The multi-head self-attention network compares each of the embedded token 312, 314, and embedded geometry data 316 with every other embedded token 312, 314, and embedded geometry data 316 as respective token pairs to compute attention scores that quantify relational patterns among the embedded tokens 312, 314, and embedded geometry data 316. In one example, the multi-head self-attention network uses a scaled dot-product followed by a Softmax function to generate normalized attention weights for each embedded token pair. Each head in the multi-head self-attention operation performs the computation independently, thereby extracting parallel relational patterns, such as alignment between arcs and points or shared parameters among closely related constraints. The output of each multi-head self-attention operation is aggregated and passed through feed-forward transformations, generating contextualized geometry and constraint embeddings 321. Contextualized geometry and constraint embeddings 321 includes embeddings corresponding to types of the constraints representing various possible geometric relationships in the input sketch, along with embeddings of geometry and sentinel tokens.

Gatherer 322 is a module that processes contextualized geometry and constraint embeddings 321 and input sketch constraints 317 to generate gathered constraints 323. Input sketch constraints 317 represent the relationships between geometric entities found in an input sketch including the type of the constraints and geometric entity identifiers for the geometric entities in the input sketch that are associated with the constraint. Gatherer 322 uses contextualized geometry and constraint embeddings 321 to convert each constraint in input sketch constraints 317 into a sequence of embeddings in gathered constraints 323. Each input sketch constraint 317 includes a constraint type and one or more geometric entity identifiers, which is converted into a sequence of embeddings in gathered constraints using corresponding embeddings from contextualized geometry and constraint embeddings 321.

Decoder 324 is a causal transformer that receives gathered constraints 323, and next-token probability distributions 329 to generate pointers 326. At each decoding step, decoder 324 receives the gathered constraints 323 from a key-value memory. Decoder 324 uses the gathered constraints 323 to represent the prompt as a ground truth constraint sequence. Decoder 324 performs masked self-attention to the concatenated autoregressive sequence, which includes the prompt, using a causal transformer so that each token attends only to earlier tokens and thereby preserves the order of the constraint sequence 330. The results of the masked self-attention pass through a linear projection layer to generate pointers 326.

Pointers 326 are vectors generated by decoder 324 during each decoding iteration. Each of the generated pointers 326 points to tokens within a dynamic vocabulary that includes sentinel tokens 302, constraint tokens 304, and geometry data 306. Thus, the generated pointers 326 suggest the most relevant tokens from contextualized geometry and constraint embeddings 321 to consider as a next token in constraint sequence 330. Pointers 326 with higher confidence scores provided by decoder 324 are more likely to be selected as a next token in constraint sequence 330. Pointers 326 are provided to the pointer network 328.

Pointer network 328 receives pointers 326 and contextualized geometry and constraint embeddings 321. Pointer network 328 determines a similarity between pointers 326 and contextualized geometry and constraint embeddings 321 (e.g., using a matrix multiplication or dot product) to produce logits, which are unnormalized real-valued numbers. Pointer network 328 then applies a Softmax function to the logits to generate next-token probability distribution 329. Constraint generation model 318 selects the token with the highest probability in the next-token probability distribution 329. Constraint generation model 318 appends the selected token with the highest probability to the constraint sequence 330. The autoregressive loop of decoder 324 and pointer network 328 continues until constraint generation model 318 selects the end-of-sequence token <EOS>, thereby completing the generation of constraint sequence 330. Constraint generation model 318 provides the constraint sequence 330 as the generated constraints 136.

Constraint sequence 330 is an ordered list of discrete tokens that represents the complete set of constraints for the input sketch. Constraint sequence 330 is generated autoregressively by successively appending each token selected by pointer network 328 from an initial <SOS> sentinel through a final <EOS> sentinel. The constraint sequence 330 can include sentinel tokens 302 that represent control symbols such as end-of-prompt token <EOP> or end-of-sequence token <EOS>. Constraint sequence 330 can also include constraint tokens 304. Each constraint token in constraint tokens 304 corresponds to a geometric relationship between geometric entities in the input sketch. The geometric entities include, without limitation, points, lines, arcs, circles, polygons, or composite curves. For example, the geometric relationships include such relationships as <PARALLEL>, <PERPENDICULAR>, <TANGENT>, <HORIZONTAL>, and/or the like. The geometric relationships could also include dimension types, such as <LINEAR-DIMENSION> and/or the like of a geometric entity in the input sketch. Constraint sequence 330 can further include geometry identifiers that reference embedded geometry data 316 by index, thereby binding each constraint to one or more geometric entities in the input sketch.

FIG. 4 is a more detailed illustration of geometry embedding layer 310, according to various embodiments. As shown, geometry embedding layer 310 receives geometry data 306 and generates embedded geometry data 316. Geometry embedding layer 310 includes, without limitation, a point embedding layer 410, an entity type embedding layer 412, a construction status embedding layer 414, a locked status embedding layer 416, and a token pooling transformer 426. Geometry data 306 includes, without limitation, point data 402, entity type tokens 404, construction status tokens 406, and locked status tokens 408. Point embedding layer 410 uses point data 402 to generate embedded point data 418. Entity type embedding layer 412 uses entity type tokens 404 to generate embedded entity type tokens 420. Construction status embedding layer 414 uses construction status tokens 406 to generate embedded construction status tokens 422. Locked status embedding layer 416 uses locked status tokens 408 to generate embedded locked status tokens 424. Token pooling transformer 426 uses embedded point data 418, embedded entity type tokens 420, embedded construction status tokens 422, and embedded locked status tokens 424 to generate embedded geometry data 316.

Each point in the point data 402 represents the coordinates (e.g., Cartesian coordinates) of some portion of a geometric entity in the input sketch. Point data 402 includes continuous numerical values representing coordinates of the corresponding points to avoid the loss of information from quantization. Each entity type token in the entity type tokens 404 represents the type of the geometric entity. Examples of the entity type tokens include a point, a line, an arc, a circle, and/or the like. Each construction status token in construction status tokens 406 represents whether a geometric entity is construction geometry. Construction geometry refers to any geometric entity that provides reference or aid to apply constraints to the input sketch. In some embodiments, point data 402 are generated by sampling multiple points along curves (e.g., at uniformly spaced parametric or arc-length intervals) or other geometric entities within the input sketch. Point data 402 and entity type tokens 404 capture local curvature and geometric information including curvature, shape, and relative spatial relationships. This allows constraint generation model 318 to capture relationships such as tangency, concentricity, and equal-radius constraints that would be ambiguous if only endpoints were used to encode the geometric entities. In some examples, construction geometry represents lines and other indicia that provide additional detail on the geometric entities in the input sketch but are not actually part of the geometry of the one or more objects depicted in the input sketch. Each locked status token in locked status tokens 408 represents whether a geometric entity is linked or fixed. A linked geometry includes a geometric entity that is associated to another sketch. A fixed geometry includes a geometric entity that is locked in position (e.g., a fixed line).

Point embedding layer 410 receives point data 402 and generates embedded point data 418. Point embedding layer 410 includes a multi-layer perceptron. The multi-layer perceptron encodes the coordinates in each of the point data 402. The embedded point data are then concatenated into a vector as embedded point data 418.

Entity type embedding layer 412 receives entity type tokens 404 and generates embedded entity type tokens 420. Entity type embedding layer 412 includes a learned embedding table (e.g., PyTorch learned table torch.nn. Embedding). The learned embedding table encodes the entity types in each of the entity type tokens 404. The embedded entity type tokens are then concatenated into a vector as embedded entity type tokens 420.

Construction status embedding layer 414 receives construction status tokens 406 and generates embedded construction status tokens 422. Construction status embedding layer 414 includes a learned embedding table (e.g., PyTorch learned table torch.nn. Embedding). The learned embedding table encodes the construction status in each of the construction status tokens 406. The embedded construction status tokens are then concatenated into a vector as embedded construction status tokens 422.

Locked status embedding layer 416 receives locked status tokens 408 and generates embedded locked status tokens 424. Locked status embedding layer 416 includes a learned embedding table (e.g., PyTorch learned table torch.nn. Embedding). The learned embedding table encodes locked status in each of the locked status tokens 408. The embedded locked status tokens are then concatenated into a vector as embedded locked status tokens 424.

Token pooling transformer 426 receives and aggregates embedded point data 418, embedded entity type tokens 420, embedded construction status tokens 422, and embedded locked status tokens 424 to generate embedded geometry data 316. In some embodiments, token pooling transformer 426 is implemented as a miniature transformer encoder that prepends a learnable pooling token (e.g., a classification token [CLS]) to embedded point data 418, embedded entity type tokens 420, embedded construction status tokens 422, and embedded locked status tokens 424. Then, token pooling transformer 426 applies one or more self-attention layers to exchange information between embedded point data 418, embedded entity type tokens 420, embedded construction status tokens 422, and embedded locked status tokens 424. Token pooling transformer 426 then provides the final hidden state of the pooling tokens as embedded geometry data 316.

### Constraint Generation Model Training

FIG. 5 is a more detailed illustration of the SFT module 110 of FIG. 1, according to various embodiments. As shown, SFT module 110 includes, without limitation, a training data preparation module 504, and a supervised training module 514. Supervised training module 514 includes, without limitation, a variable length prompt generator 508, a prompt 510, and a completion 512. In operation, SFT module 110 performs a two-stage supervised learning that first performs broad supervised fine-tuning and then performs a short, high quality data fine-tuning on constraint generation model 318. Training data preparation module 504 uses training data 502 to generate training data elements 506. Variable length prompt generator 508 uses training data elements 506 to generate prompt 510 and completion 512. Supervised training module 514 uses prompt 510 and completion 512 to update constraint generation model 318.

Training data 502 includes one or more training data elements, which are used to train constraint generation model 318. Training data 502 can be loaded from data store 122 or some other source. Each training data element includes an input sketch and a ground truth constraint sequence for the sketch. A sketch can be included in multiple training data elements when more than one ground truth constraint sequence is available for that sketch. In some cases, the ground truth constraint sequences are generated by human designers, a reference constraint generator, and/or the like. Some input sketches include a partial set of constraints. Under constrained (UC) sketches include geometric entities that still have some unconstrained degrees of freedom. Fully constrained (FC) sketches include geometric entities whose degrees of freedom are completely determined. Over-constrained (OC) sketches include geometric entities with more constraints than degrees of freedom.

Training data preparation module 504 within SFT module 110 receives training data 502. Training data preparation module 504 first filters the received training data 502 to ensure that there are a sufficient number of training data elements that include a sketch that is fully constrained. For example, the filtering ensures that at least ten percent of the geometric entities in each sketch within the training data elements are fully constrained. Filtering training data 502 to include training data elements that have a higher percentage of fully-constrained geometric entities improves convergence of constraint generation model 318 during training.

Training data preparation module 504 then performs augmentation on training data 502. The objective of augmentation is to increase the number of training data elements in training data 502 while also increasing the geometric diversity of training data 502. Training data preparation module 504 performs one or more augmentation operations on selected training data examples. The one or more augmentation operations perform at least one change to the geometry of the input sketch of a training data example and also make one or more corresponding changes in the ground truth constraint sequence so as to preserve the geometric correctness of the ground truth constraint sequence for the augmented training data element.

Examples of the one or more augmentation operations include, without limitation, a rotation operation, a scale operation, a mirror operation, a translation operation to one or more of the geometric entities within a sketch of a training data example. For example, a rotation operation rotates a sketch or a portion of the geometric entities in the sketch around a specific point such as a center point or a construction point by a random angle (e.g., 15 degrees). A scale operation uniformly enlarges or reduces the size of the entire sketch, or a subset of geometric entities within the sketch, relative to a reference point, such as a center point or a construction point. For example, scaling all geometric entities within a sketch by a factor of 2 increases each dimension of the sketch by 100%, while scaling by a factor of 0.5 reduces each dimension by half, resulting in a proportionally smaller sketch. A mirror operation flips a sketch or a portion of the geometric entities the sketch across a certain axis (e.g., X axis, Y axis, or other axis at any orientation) to create a mirror image of the sketch or the portion of the geometric entities in the sketch. A translation operation translates all the points within a sketch, or the points associated with a portion of the geometric entities with the sketch. The translation moves or shifts the points a random distance in a random direction (e.g., shift all points across X axis by 10 points). Training data preparation module 504 recalculates any constraints affected by the performing augmentation. For example, a rotation operation can change constraint orientations (e.g., a 90-degree rotation transforms a horizontal constraint into a vertical constraint or vice versa). A scale operation affects both relative sizes and distances (e.g., scaling a sketch by a factor of 2 doubles all distances, requiring updates to constraints dimensions). A mirror operation can alter relative constraint positions (e.g., mirroring across the Y-axis changes left-side constraints into right-side constraints, requiring updates to constraints positions and directions). A translation operation can adjust relative distances between geometric entities (e.g., shifting geometric entities differently along an axis necessitates recalculating distance constraints).

Once filtering and augmentation are completed, training data preparation module 504 generates a set of training data elements 506. The set of training data elements 506 then becomes the training data to be used by supervised training module 514 when training constraint generation model 318.

Variable length prompt generator 508 receives a training data element selected by supervised training module 514 from the set of training data elements 506. Variable length prompt generator 508 then converts the selected training data element into a prompt 510 and a completion 512 constraint sequence. Variable length prompt generator 508 randomly partitions the ground truth constraint sequence into two sets of the constraints. A first set of the constraints is added to prompt 510 and a second set of the constraints is added to completion 512. Prompt 510 and completion 512 are concatenated and become the ground truth for the newly created training data example. Placing a portion of the constraints in the ground truth constraint sequence in prompt 510 provides further diversity in the training data and also provides a richer example of good constraints during training. Variable length prompt generator 508 partitions the ground truth constraint sequence so that anywhere from zero to eighty percent of the constraints in the ground truth constraint sequence are present in prompt 510. In some cases, multiple prompts 510 with different portions of the constraints in the ground truth constrain sequence can be generated to provide additional training data elements for use by supervised training module 514.

Supervised training module 514 receives prompt 510 and completion 512. In some examples, supervised training module 514 further adds a token to prompt 510 to indicate whether the input sketch in the prompt is fully constrained. In some cases, supervised training module 514 further adds a fully-constrained status token to the prompt to enable classifier-free guidance during the training. Supervised training module 514 then presents the prompt 510 to constraint generation model 318. Constraint generation model 318 then autoregressively generates a constraint sequence (e.g., constraint sequence 330). Supervised training module 514 then compares the constraint sequence generated by constraint generation model 318 to the ground truth to determine a loss. For example, supervised training module 514 can determine the loss using the cross-entropy loss of Equation 1:

$$ℒ = - {\sum }_{i = 1}^{N} log {p}_{θ} ( {y}_{i} \vert {y}_{< i} ) \qquad Equation 1$$

Where N is the length of the ground truth, yᵢ is the i-th ground truth token within the ground truth. y_{<i} shows the ordered list of ground truth tokens at all positions before i. p_{θ} shows the probability function that quantifies how well the generated constraint sequence generated by constraint generation model 318 is with respect to the ground truth. θ refers to a set of trainable parameters of constraint generation model 318 (e.g., weight matrices and bias vectors).

Supervised training module 514 uses gradients of the cross-entropy loss to update constraint generation model 318 by backpropagation. Supervised training module 514 continues training by selecting new training data elements from the set of training data elements 506, using variable length prompt generator 508 to generate additional prompts 510 and completion 512, and using additional losses to update constraint generation model 318. The training continues until an exit criterion is met. In some examples, supervised training module 514 stops training when the training over k consecutive training epochs results in limited further improvement in the ability of constraint generation model 318 to generate constraint sequences. In some examples, supervised training module 514 stops training after a predetermined number of training epochs. In some embodiments, supervised training module 514 further stores the updated constraint generation model 318 in data store 122 as trained model 124.

After initial training by supervised training module 514, supervised training module 514 fine tunes the constraint generation model 318. During fine tuning supervised training module 514 receives high quality training data that includes a selected subset of fully constrained sketches that do not include redundant or conflicting constraints. High quality training data includes sketches with minimal degrees of freedom and/or stable sketches validated by a solver. In some examples high quality training data includes one or more user validated fully constraint sketches.

During fine tuning supervised training module 514 provides each sketch in high quality training data to constraint generation model 318 using high quality ground truth prompts and completions to generate a constraint sequence (e.g., constraint sequence 330). Supervised training module 514 then compares the constraint sequence generated by constraint generation model 318 to the corresponding high quality ground truth constraint sequence for the sketch to determine a loss. For example, supervised training module 514 can determine the loss using the cross-entropy loss of Equation 1. Where N is the length of high-quality training data, yᵢ is the i-th high quality training data token. y_{<i} shows the ordered list of high quality training data tokens at all positions before i. p_{θ} shows the probability function that quantifies how well the generated constraint sequence generated by constraint generation model 318 is with respect to high quality training data token. θ refers to a set of trainable parameters of constraint generation model 318 (e.g., weight matrices and bias vectors).

Supervised training module 514 uses gradients of the cross-entropy loss to update constraint generation model 318 by backpropagation. Supervised training module 514 continues training by selecting new training data elements from high quality training data and using additional losses to update constraint generation model 318. The training continues until an exit criterion is met. In some examples, supervised training module 514 stops training when the training over k consecutive training epochs results in limited further improvement in the ability of constraint generation model 318 to generate constraint sequences. In some examples, supervised training module 514 stops training after a predetermined number of training epochs. In some embodiments, supervised training module 514 further stores the updated constraint generation model 318 in data store 122 as trained model 124.

### Constraint Generation Model Scoring and Training

FIG. 6 is a more detailed illustration of the scoring module 112 of FIG. 1, according to various embodiments. As shown, scoring module 112 receives an input sketch 602 and a candidate constraint sequence 604 generated by constraint generation model 318 to generate quality scores 612. Scoring module 112 includes, without limitation, a constraint solver 606, a design intent score function 608, and a stability score function 610. Constraint generation model 318 uses an input sketch 602 to generate candidate constraint sequence 604.

Input sketch 602 can be loaded from data store 122 or some other source. In some examples, input sketch 602 includes a partial set of constraints, indicating that the input sketch 602 is at least partially constrained.

Constraint generation model 318 receives input sketch 602 and generates candidate constraint sequence 604. Constraint generation model 318 is the constraint generation model trained by SFT module 110. In some embodiments, constraint generation model 318 is trained model 124 previously stored in data store 122.

Candidate constraint sequence 604 is an ordered list of discrete tokens that represents the complete set of constraints for the input sketch 602. Candidate constraint sequence 604 can include sentinel tokens 302 that represent control symbols such as end-of-prompt token <EOP> or end-of-sequence token <EOS>. Constraint sequence 330 also includes constraint tokens 304. Each constraint token in constraint tokens 304 corresponds to a geometric relationship between geometric entities in the input sketch 602. The geometric entities include, without limitation, points, lines, arcs, circles, polygons, or composite curves. For example, the geometric relationships include such relationships as <PARALLEL>, <PERPENDICULAR>, <TANGENT>, <HORIZONTAL>, and/or the like. The geometric relationships could also include dimension types, such as <LINEAR-DIMENSION> and/or the like of a geometric entity in the input sketch 602.

Constraint solver 606 receives input sketch 602 along with candidate constraint sequence 604. Constraint solver 606 analyzes the constraints from candidate constraint sequence 604 and input sketch 602 to generate a sketch solution and to evaluate the constraints and provide feedback on the degrees of freedom in input sketch 602 and whether input sketch is fully constrained or over constrained. Constraint solver 606 determines the exact position, orientation, and dimension of geometric entities within input sketch 602 based on candidate constraint sequence 604 using a numerical solver or other suitable technique.

Constraint solver 606 determines the remaining DOFs of candidate constraint sequence 604. In addition, constraint solver 606 determines the convergence status of the sketch solution. Constraint solver 606 can determine whether candidate constraint sequence 604 is under constrained, over constrained, or has contradictory constraints that prevent convergence. For example, if candidate constraint sequence 604 is under constrained, the input sketch 602 has remaining DOF and flexibility. Or if candidate constraint sequence 604 is over constrained or has contradictory constraints, one or some of the constraints are redundant or one or some of the constraints have a conflict with other constraints in candidate constraint sequence 604.

Design intent score function 608 receives the sketch solution from constraint solver 606 and generates a design intent score based on multiple scores. The multiple scores include, without limitation, a DOF score, a regularity score, a constraint to dimension ratio score, and/or the like. In some cases, design intent score function 608 measures the remaining DOFs and assigns a higher DOF score when there are fewer remaining DOFs and assigns a lower DOF score when there are more remaining DOFs (e.g., a fully constrained sketch solution receives the highest DOF score). Design intent score function 608 penalizes an over constrained sketch solution. Thereby, lowering the design intent score in proportion to the contradictory constraints.

Design intent score function 608 generates the regularity score, by perturbing one or more dimensions in the sketch solution and uses the constraint solver 606 to update the sketch solution. If the number of constraints in the updated sketch solution equals the number of constraints in the sketch solution before perturbation, design intent score function 608 assigns a higher regularity score. Otherwise, design intent score function 608 assigns a lower regularity score in proportion to the number of added or removed constraints in the updated sketch solution after the perturbation.

Design intent score function 608 generates the constraint to dimension ratio score by counting the number of constraints, dimensions (e.g., lengths, angles, radii, diameters, and/or the like), and geometric entities in the sketch solution. In some examples, design intent score function 608 computes a constraint to dimension ratio using one or more metrics. In operation, design intent score function 608 computes a constraint to dimension ratio by dividing the number of constraints by the number of dimensions. In some examples, design intent score function 608 computes a second constraint to dimension ratio by dividing the number of dimensions by the number of geometric entities. In some examples, design intent score function 608 computes a third constraint to dimension ratio by an exponential term exp(^{-(i×C+j×D)}/_{k×E}). Where C is the number of constraints, D is the number of dimensions, E is the number of geometric entities, and i, j, k are tunable hyperparameters. Design intent score function 608 assigns a constraint to dimension ratio score proportional to the constraint to dimension ratio (e.g., a higher constraint to dimension ratio provides a higher constraint to dimension ratio score). Design intent score function 608 aggregates the DOF score, regularity score, and constraint to dimension ratio score to generate a design intent score for each input sketch 602.

Stability score function 610 receives the sketch solution from constraint solver 606 along with input sketch 602 to generate a stability score based on multiple metrics. Stability score function 610 generates stability estimates based on the positional displacement of geometric entities in the sketch solution relative to the position of geometric entities in input sketch 602 after constraint solver 606 utilizes candidate constraint sequence 604. Constraint solver 606 analyzes candidate constraint sequence 604 to determine the positions and orientations of geometric entities. Constraint solver 606 can alter the positions and orientations of geometric entities to satisfy convergence of the sketch solution. The multiple metrics include, without limitation, a normalized distance and a cell-based comparison. Stability score function 610 uses the metrics to measure the positional displacement of the geometric entities in the sketch solution relative to input sketch 602. A sketch solution with low positional displacement of the geometric entities relative to the input sketch 602 receives a higher stability score. If the geometric entities in the sketch solution displace relative to the geometric entities of input sketch 602, the sketch solution receives a lower stability score proportional to the amount of displacement (e.g., a higher amount of displacement results in a lower stability score).

Stability score function 610 measures the normalized distance between multiple points on the sketch solution and input sketch 602. In operation, stability score function 610 measures multiple distances (e.g., Euclidean distance) among multiple points within the sketch solution and normalizes the multiple distances to the diagonal distance of the bounding box in the sketch solution. A bounding box refers to the smallest rectangle that entirely encloses the geometry of a sketch. Next, stability score function 610 measures the multiple distances among the corresponding multiple points within the input sketch 602 and normalizes the multiple distances to the diagonal distance of the bounding box in the input sketch 602. Stability score function 610 then computes the absolute value of the difference between the multiple normalized distances of the sketch solution and the multiple normalized distances of the input sketch 602. Stability score function 610 assigns the stability score proportional to the absolute value.

Stability score function 610 compares the number of multiple points within one or more cells in the sketch solution and input sketch 602. In operation, stability score function 610 assigns one or more cells such as squares or rectangles with predefined size to the sketch solution and input sketch 602. Stability score function 610 tracks the cells that each point occupies in the sketch solution and input sketch 602. Next, stability score function 610 measures the number of points that are located in the same cell in the sketch solution and input sketch 602. Stability score function 610 assigns a stability score proportional to the number of points that are located in the same cell in both sketch solution and input sketch 602. Stability score function 610 generates the stability score based on normalized distance and/or cell-based comparison for the input sketch 602.

Scoring module 112 aggregates the stability score received from stability score function 610 and the design intent score received from design intent score function 608 to generate quality scores 612. Quality scores 612 includes, without limitation, the DOF score, the regularity score, the constraint to dimension ratio score, and stability score. Constraint solver 606 determines when contradictory constraints or redundant constraints prevent convergence. If such contradictions or redundancies are detected and prevent convergence, scoring module 112 sets quality scores 612 of associated candidate constraint sequence 604 to zero.

FIG. 7 is a more detailed illustration of the preference-based optimization module 116 of FIG. 1, according to various embodiments. As shown, preference-based optimization module 116 includes, without limitation, a filter and sampler 702, a cross-entropy loss 706, and a Bradley-Terry model 712. Constraint generation model 318 generates a plurality of candidate constraint sequences 604(i) from a plurality of input sketches 602(i). Scoring module 112 uses input sketches 602(i) and candidate constraint sequences 604(i) to generate a plurality of quality scores 612(i). Filter and sampler 702 uses candidate constraint sequences 604(i) and quality scores 612(i) to generate expert sequence 704 and pair-wise sequences 710. Cross-entropy loss 706 uses expert sequence 704 and a plurality of next-token probability distributions 703(i) to generate updated model using ExIt 708. Bradley-Terry model 712 uses pair-wise sequences 710 to generate updated model using DPO 714.

In some embodiments, a set of M input sketches 602 can be loaded from data store 122 or some other source, where M≥1. In some examples, each input sketch 602(i) includes a partial set of constraints, indicating that each input sketch 602(i) is at least partially constrained.

Constraint generation model 318 receives each input sketch 602(i) and generates a corresponding set of M candidate constraint sequences 604(i). Constraint generation model 318 is the constraint generation model trained by SFT module 110. In some embodiments, constraint generation model 318 is trained model 124 previously stored in data store 122.

Each candidate constraint sequence 604(i) is an ordered list of discrete tokens that represents the complete set of constraints for the corresponding input sketch 602(i) generated by constraint generation model 318 from input sketch 602. Each candidate constraint sequence 604(i) can include sentinel tokens 302 that represent control symbols such as end-of-prompt token <EOP> or end-of-sequence token <EOS>. Constraint sequence 330 can also include constraint tokens 304. Each constraint token in constraint tokens 304 corresponds to a geometric relationship between geometric entities in each input sketch 602(i). The geometric entities include, without limitation, points, lines, arcs, circles, polygons, or composite curves. For example, the geometric relationships include such relationships as <PARALLEL>, <PERPENDICULAR>, <TANGENT>, <HORIZONTAL>, and/or the like. The geometric relationships could also include dimension types, such as <LINEAR-DIMENSION> and/or the like of a geometric entity in each input sketch 602(i).

Scoring module 112 receives each input sketch 602(i) and each corresponding candidate constraint sequence 604(i) to generate a sketch solution for each input sketch 602(i) and each corresponding candidate constraint sequence 604(i) using constraint solver 606. Scoring module 112 then generates quality scores 612(i) using design intent score function 608 and stability score function 610. Quality scores 612(i) quantifies the stability and DOFs of each candidate constraint sequence 604(i).

Filter and sampler 702 first samples a specified number of constraint sequences for each input sketch 602 at a particular temperature parameter. Filter and sampler 702 then filters constraint sequences by removing any candidate constraint sequence 604(i) flagged as under-constrained, over-constrained, unsolvable, or otherwise not meeting predefined quality criteria based on corresponding quality scores 612(i). In some cases, filter and sampler 702 uses a sample count parameter and/or a temperature parameter to sample constraint sequences. The sample count parameter is a numeric quantity (e.g., 5, 10, or 128) that determines the size of generated expert sequences 704 or pair-wise sequences 710. The temperature parameter adjusts the probability distribution at each sampling step. For example, a temperature parameter of T=1 is considered standard or neutral temperature, but higher temperatures make the sampling probability more random.

For expert iteration optimization, filter and sampler 702 samples a specified number of constraint sequences based on the sample count parameter and the temperature parameter to generate expert sequence 704. Expert sequence 704 includes the sequences that converge successfully and have low DOFs.

Cross-entropy loss 706 performs cross entropy during expert iteration optimization. Cross-entropy loss 706 receives expert sequence 704, which represents high-quality constraint sequences having successfully converged and exhibiting minimal DOF. Cross-entropy loss 706 also receives next-token probability distribution 703 generated by the constraint generation model 318 from the pointer network 328. Cross-entropy loss 706 computes a cross-entropy loss value by comparing each token in expert sequence 704 against next-token probability distribution 703 generated by constraint generation model 318. Cross-entropy loss 706 measures the negative log-likelihood of the expert sequence 704 given next-token probability distribution 703. For example, cross-entropy loss 706 can determine the loss using the cross-entropy loss of Equation 1. Where N is the length of expert sequence 704, yᵢ is the i-th token within expert sequence 704. y_{<i} shows the ordered list tokens within expert sequence 704 at all positions before i. p_{θ} shows the probability function that quantifies how well the generated constraint sequence generated by constraint generation model 318 is with respect to expert sequence 704. θ refers to a set of trainable parameters of constraint generation model 318 (e.g., weight matrices and bias vectors).

The computed cross-entropy loss is differentiated with respect to the parameters of the constraint generation model 318, generating gradients that guide adjustments to the parameters through backpropagation. Iterative minimization of the cross-entropy loss thus improves the capability of constraint generation model 318 to generate candidate constraint sequence 604 similar to the expert sequence 704. The updated constraint generation model 318 using expert iteration optimization is provided as updated model using ExIt 708. Updated model using ExIt 708 can be stored as trained model 124 in data store 122.

For direct preference optimization, filter and sampler 702 samples a specified number of candidate constraint sequences 604(i) based on the sample count parameter and the temperature parameter to generate pair-wise sequences 710. Pair-wise sequences 710 includes pairs of sequences that converge successfully and have low DOFs. Filter and sampler 702 designates one sequence in each pair as superior, indicating a higher fraction of fully constrained geometry relative to the other sequence based on constraint solver 606 feedback.

Bradley-Terry model 712 performs DPO using each pair of sequences in the pair-wise sequences 710. Each pair of constraint sequences in pair-wise sequences 710 is compared based on how well each constraint sequence constrains the input sketch 602. Bradley-Terry model 712 performs pairwise comparisons using a Bradley-Terry statistical model combined with a logistic-based ranking function to convert pairwise comparisons into reward signals. The Bradley-Terry model is a statistical model that estimates the likelihood of one constraint sequence in a pair of constraint sequences being chosen over the other constraint sequence in a pair of constraint sequences based on pairwise comparisons. The Bradley-Terry model transforms each pairwise comparison into an implicit reward signal that favors the candidate constraint sequence in each pair that achieves a greater degree of full constraint. A logistic-based ranking function (e.g., a logistic sigmoid function) converts the output of the Bradley-Terry model into a continuous scale (e.g., range of real numbers between zero and one). The reward favors constraint sequences with higher rankings. Bradley-Terry model 712 additionally applies a penalty term to prevent large changes from being made to the constraint generation model 318, unless such deviations result in more fully constrained sketches. Bradley-Terry model 712 converts the reward and penalty into a preference-based loss that is differentiable with respect to the parameters of constraint generation model 318. Bradley Terry model 712 calculates gradients of the preference-based loss with respect to the parameters of constraint generation model 318. Bradley-Terry model 712 applies calculated gradients through backpropagation to update constraint generation model 318. The updated constraint generation model 318 using direct preference optimization is provided as updated model using DPO 714. Updated model using DPO 714 can be stored as trained model 124 in data store 122.

FIG. 8 is a more detailed illustration of the reinforcement learning module 118 of FIG. 1, according to various embodiments. As shown, reinforcement learning module 118 includes, without limitation, a constraint filter and sampler 802, a per constraint reward function 804, a penalty function 806, a per constraint policy gradient module 808, a sequence filter and sampler 812, a per sequence reward function 814, and a per sequence policy gradient module 816. Constraint generation model 318 uses input sketch 602 to generate candidate constraint sequence 604. Scoring module 112 uses input sketch 602 and candidate constraint sequence 604 to generate quality scores 612. Constraint filter and sampler 802 uses candidate constraint sequence 604 and quality scores 612 to generate sampled constraints. Per constraint policy gradient module 808 uses per constraint reward function 804 and penalty function 806 to generate updated model using per constraint policy gradient 810. Per sequence policy gradient module 816 uses per sequence reward function 814 to generate updated model using per sequence policy gradient 818.

Input sketch 602 can be loaded from data store 122 or some other source. In some examples, input sketch 602 includes a partial set of constraints, indicating that the input sketch 602 is at least partially constrained.

Constraint generation model 318 receives input sketch 602 and generates candidate constraint sequence 604. Constraint generation model 318 is the constraint generation model trained by SFT module 110. In some embodiments, constraint generation model 318 is trained model 124 previously stored in data store 122.

Candidate constraint sequence 604 is an ordered list of discrete tokens that represents the complete set of constraints for the input sketch 602 generated by constraint generation model 318 from input sketch 602. Candidate constraint sequence 604 can include sentinel tokens 302 that represent control symbols such as end-of-prompt token <EOP> or end-of-sequence token <EOS>. Constraint sequence 330 can also include constraint tokens 304. Each constraint token in constraint tokens 304 corresponds to a geometric relationship between geometric entities in the input sketch 602. The geometric entities include, without limitation, points, lines, arcs, circles, polygons, or composite curves. For example, the geometric relationships include such relationships as <PARALLEL>, <PERPENDICULAR>, <TANGENT>, <HORIZONTAL>, and/or the like. The geometric relationships could also include dimension types, such as <LINEAR-DIMENSION> and/or the like of a geometric entity in the input sketch 602.

Scoring module 112 receives input sketch 602 and candidate constraint sequence 604 to generate a sketch solution using constraint solver 606. Scoring module 112 then generates quality scores 612 using design intent score function 608 and stability score function 610. Quality scores 612 quantifies the stability and DOFs of the candidate constraint sequence 604.

Constraint filter and sampler 802 receives candidate constraint sequence 604 and associated quality scores 612 generated by scoring module 112. Constraint filter and sampler 802 evaluates candidate constraint sequence 604 using quality scores 612. Constraint filter and sampler 802 samples a specific number of constraints for each candidate constraint sequence 604 at a particular temperature parameter to generate sampled constraints. Constraint filter and sampler 802 then flags constraints within sampled constraints which are related to over constrained sketches, unsolvable sketches, unstable sketches, and other failures using quality scores 612. In some cases, constraint filter and sampler 802 uses a sample count parameter and/or a temperature parameter to sample constraints. The sample count parameter is a numeric quantity (e.g., 5, 10, or 128) that determines the size of generated sampled constraints. The temperature parameter adjusts the probability distribution at each sampling step. For example, a temperature parameter of T=1 is considered standard or neutral temperature, but higher temperatures make the sampling probability more random. Constraint filter and sampler 802 provides sampled constraints to a per constraint reward function 804 and a penalty function 806.

Per constraint reward function 804 receives sampled constraints from constraint filter and sampler 802. Per constraint reward function 804 generates rewards proportionally to the number of fully constrained geometric entities (e.g., a line with zero DOF) associated with each constraint in sampled constraints over all geometric entities. The geometric entities include, without limitation, points, lines, arcs, circles, polygons, or composite curves. Rewards increase the overall desirability of rewarded constraints in the per-constraint reinforcement learning process, encouraging similar constraints in subsequent generations. Optionally, per constraint reward function 804 can generate an additional Kullback-Leibler (KL) penalty term to control excessive divergence. Per constraint reward function 804 provides rewards to the per constraint policy gradient module 808. For example, per constraint reward function 804 can determine the KL penalty using the formula of Equation 2:

$${ℒ}_{K L} = {β}_{K L} {\sum }_{i} {p}_{θ} ( {c}_{i} \vert {c}_{< i} ) log \frac{{p}_{θ} ( {c}_{i} \vert {c}_{< i} )}{{p}_{{θ}_{r}} ( {c}_{i} \vert {c}_{< i} )} \qquad Equation 2$$

Where β_{KL} is a tunable hyperparameter controlling the strength of the KL penalty term, cᵢ is the i-th constraint within sampled constraints. c_{<i} shows the ordered list constraint within sampled constraints at all positions before i, p_{θ}_{ᵣ} shows the probability function based on constraint generation model 318 trainable parameters θᵣ, θᵣ refers to a set of trainable parameters of constraint generation model 318 (e.g., weight matrices and bias vectors), p_{θ} shows the probability function based on the latest update of constraint generation model 318 or current constraint generation model 318 under reinforcement learning process parameterized by the trainable weights θ.

Penalty function 806 receives sampled constraints from constraint filter and sampler 802. Penalty function 806 applies penalties to the sampled constraints which are flagged by constraint filter and sampler 802. The flagged sampled constraints include constraints within over constrained sketches, unsolvable sketches, unstable sketches, and other failures. Penalty function 806 applies penalties proportional to the severity of the flagged sampled constraints (e.g., highest penalty for the constraints within unstable sketches). Penalties reduce the overall desirability of the penalized constraints in the per-constraint reinforcement learning process, discouraging similar constraints in subsequent generations. Penalty function 806 provides penalties to the per constraint policy gradient module 808.

Per constraint policy gradient module 808 receives rewards from per constraint reward function 804 and penalties from penalty function 806. Per constraint policy gradient module 808 computes the advantage term explicitly by subtracting the baseline (e.g., moving average of past net rewards) from the net reward, which is the reward minus penalty, generated for each constraint in sampled constraints. Per constraint policy gradient module 808 uses policy gradient techniques to adjust the parameters of constraint generation model 318 in the direction that maximizes expected future rewards. Policy gradient techniques include, but not limited to ReMax, REINFORCE-Leave-One-Out (RLOO), Group Relative Policy Optimization (GRPO), and/or the like. By weighting parameter updates according to advantages. The advantage term directly scales the gradient of the log-probability of selecting each constraint, enabling reinforcement of constraints that outperform the baseline and discouragement of constraints underperforming the baseline. Per constraint policy gradient module 808 utilizes rewards from per constraint reward function 804 and penalties from penalty function 806 to update constraint generation model 318. The updated constraint generation model 318 using per constraint reinforcement learning is provided as updated model using per constraint policy gradient 810. Updated model using per constraint policy gradient 810 can be stored as trained model 124 in data store 122.

Sequence filter and sampler 812 receives candidate constraint sequence 604 and associated quality scores 612. Sequence filter and sampler 812 identifies constraints within candidate constraint sequence 604 that are related to fully constrained sketches with zero DOF or partially constrained sketches with non-zero DOFs using quality scores 612 at each reinforcement iteration. Sequence filter and sampler 812 removes constraints within candidate constraint sequence 604 that are not needed to fully constrain input sketch 602 (e.g., unneeded constraints) to generate a first truncated constraint sequence. Sequence filter and sampler 812 then generates multiple constraint sequences based on the first truncated constraint sequence. For example, removing one constraint within candidate constraint sequence 604 by sequence filter and sampler 812 also results in a second truncated constraint sequence corresponding to the portion of candidate constraint sequence 604 prior to the removed constraint and a third truncated constraint sequence corresponding to the portion of candidate constraint sequence 604 after the removed constraint. Sequence filter and sampler 812 generates additional truncated constraint sequences based on other constraints that are removed. Alternatively, sequence filter and sampler 812 can mask out unneeded constraints to generate truncated constraint sequences without removing constraints. Sequence filter and sampler 812 then samples a specific number of truncated constraint sequences at a particular temperature parameter to generate sampled constraint sequences. In some cases, sequence filter and sampler 812 use a sample count parameter and/or a temperature parameter to sample constraint sequences. The sample count parameter is a numeric quantity (e.g., 5, 10, or 128) that determines the size of generated sampled constraint sequences. The temperature parameter adjusts the probability distribution at each sampling step. For example, a temperature parameter of T=1 is considered standard or neutral temperature, but higher temperatures make the sampling probability more random. Sequence filter and sampler 812 provides sampled constraint sequences with corresponding quality scores 612 to a per sequence reward function 814.

Per sequence reward function 814 receives sampled constraint sequences and corresponding quality scores 612 from sequence filter and sampler 812. Per sequence reward function 814 measures the fraction of fully constrained constraint sequences in sampled constraint sequences. Next, per sequence reward function 814 generates rewards proportionally to the fraction of fully constrained constraint sequences in sampled constraint sequences using quality scores 612 generated by scoring module 112. Rewards increase the overall desirability of rewarded constraint sequences in the per-sequence reinforcement learning process, encouraging similar constraint sequences in subsequent generations. Optionally, per sequence reward function 814 can generate an additional Kullback-Leibler (KL) penalty term to control excessive divergence. Per sequence reward function 814 provides rewards to the per sequence policy gradient module 816. For example, per sequence reward function 814 can determine the KL penalty using the formula of Equation 2. Where β_{KL} is a tunable hyperparameter controlling the strength of the KL penalty term, cᵢ is the i-th constraint within sampled constraints. c_{<i} shows the ordered list constraint within sampled constraints at all positions before i, p_{θ}_{ᵣ} shows the probability function based on constraint generation model 318 trainable parameters θᵣ, θᵣ refers to a set of trainable parameters of constraint generation model 318 (e.g., weight matrices and bias vectors), p_{θ} shows the probability function based on the latest update of constraint generation model 318 or current constraint generation model 318 under reinforcement learning process parameterized by the trainable weights θ.

Per sequence policy gradient module 816 receives rewards from per sequence reward function 814. Per sequence policy gradient module 816 computes the advantage term explicitly by subtracting the baseline (e.g., moving average of past net rewards) from the rewards generated for each constraint sequence in sampled constraint sequences. Per sequence policy gradient module 816 uses policy gradient techniques to adjust the parameters of constraint generation model 318 in the direction that maximizes expected future rewards. Policy gradient techniques include, but not limited to ReMax, RLOO, GRPO, and/or the like. By weighting parameter updates according to advantages. The advantage term directly scales the gradient of the log-probability of selecting each constraint sequence, enabling reinforcement of constraints that outperform the baseline and discouragement of constraint sequences underperforming the baseline. Per sequence policy gradient module 816 utilizes rewards from per sequence reward function 814, to update constraint generation model 318. The updated constraint generation model 318 using per sequence reinforcement learning is provided to updated model using per sequence policy gradient 818. Updated model using per sequence policy gradient 818 can be stored in trained model 124 in data store 122.

Reinforcement learning module 118 can iteratively (e.g., two or more times) apply per constraint policy gradient module 808 and/or per sequence policy gradient module 816, progressively updating the constraint generation model 318. The iterative update continues until an exit condition is satisfied. The exit conditions include, without limitations, reaching a predetermined convergence threshold such as minimal improvement between consecutive iterations, reaching a specified maximum number of iterations, or reaching a specified threshold for quality scores 612. Upon satisfying the exit conditions, the iterative reinforcement learning process terminates, and the updated constraint generation model 318 is stored as trained model 124 in data store 122.

### Generating a Constraint Sequence

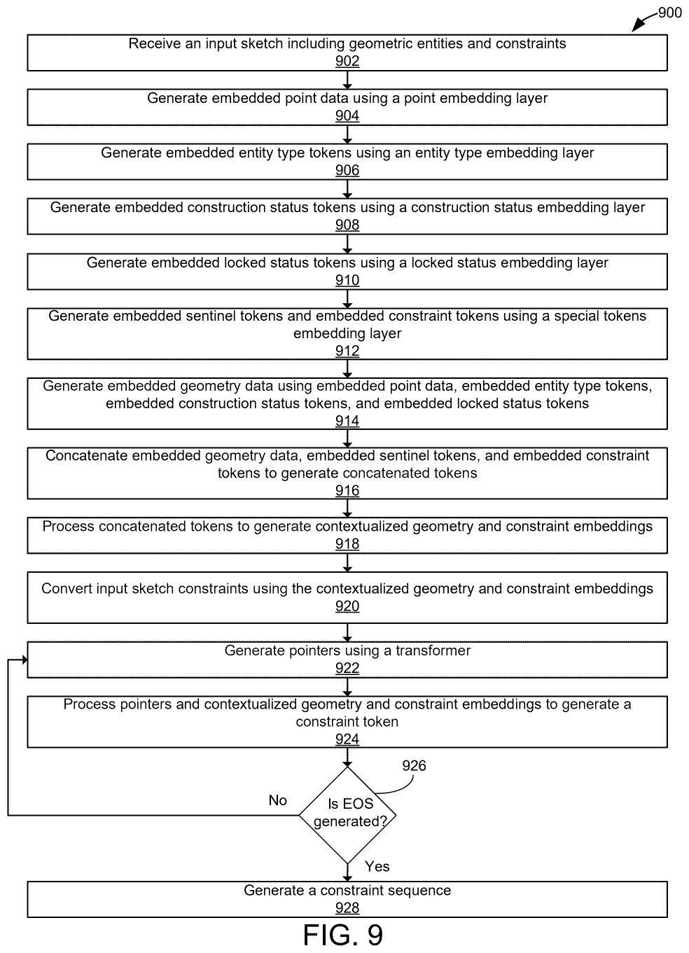

FIG. 9 is a flow diagram of method steps for generating constraint sequences from an input sketch, according to various embodiments. Although the method steps are described with reference to the embodiments of FIGS. 1-4, persons skilled in the art will understand that any system configured to implement the method steps, in any order, falls within the scope of the present disclosure.

Method 900 begins at step 902, where constraint generation application 132 receives an input sketch 134 including geometric entities and constraints. Input sketch 134 is a CAD drawing or sketch received from a user or generated by a CAD module. For example, a user can provide input sketch 134 using input devices 208. Input sketch 134 includes, without limitation, one or more geometric entities (e.g., points, lines, arcs, circles, polygons, or composite curves) and one or more constraints associated with geometric entities.

At step 904, constraint generation application 132 generates embedded point data 418 using point embedding layer 410. Constraint generation application 132 processes input sketch 134 to generate point data 402 by extracting coordinates from each geometric entity within the sketch. Each point in the point data 402 represents the coordinates (e.g., Cartesian coordinates) of some portion of a geometric entity in the input sketch. Point embedding layer 410 then encodes each point in the point data 402 to generate embedded point data. The embedded point data are then concatenated into a vector as embedded point data 418.

At step 906, constraint generation application 132 generates embedded entity type tokens 420 using entity type embedding layer 412. Constraint generation application 132 processes input sketch 134 to generate entity type tokens 404 by identifying and categorizing each geometric entity within the input sketch 134. Each geometric entity is labeled with an entity type (e.g., points, lines, arcs, circles, polygons, or composite curves). Entity type embedding layer 412 includes a learned embedding table (e.g., PyTorch learned table torch.nn. Embedding). Entity type embedding layer 412 then encodes each entity type token in entity type tokens 404 to generate embedded entity type tokens. The embedded entity type tokens are then concatenated into a vector as embedded entity type tokens 420.

At step 908, constraint generation application 132 generates embedded construction status tokens 422 using construction status embedding layer 414. Constraint generation application 132 processes input sketch 134 to generate construction status tokens 406 by identifying and evaluating the input sketch 134 to determine construction status. Construction status embedding layer 414 includes a learned embedding table (e.g., PyTorch learned table torch.nn. Embedding). Construction status embedding layer 414 then encodes each construction status token in construction status tokens 406 to generate embedded construction status tokens. The embedded construction status tokens are then concatenated into a vector as embedded construction status tokens 422.

At step 910, constraint generation application 132 generates embedded locked status tokens 424 using locked status embedding layer 416. Constraint generation application 132 processes input sketch 134 to generate locked status tokens 408 by identifying and evaluating the input sketch 134 to determine locked status. Locked status embedding layer 416 includes a learned embedding table (e.g., PyTorch learned table torch.nn. Embedding). Locked status embedding layer 416 then encodes each locked status token in locked status tokens 408 to generate embedded locked status tokens. The embedded locked status tokens are then concatenated into a vector as embedded locked status tokens 424.

At step 912, constraint generation application 132 generates embedded sentinel tokens 312 and embedded constraint tokens 314. Constraint generation application 132 processes input sketch 134 to generate sentinel tokens 302 by defining control symbols. Sentinel tokens 302 represent control symbols that include, without limitation, a start-of-sequence token <SOS>, an end-of-prompt token <EOP>, a padding token <PAD>, an end-of-sequence token <EOS>, and in some training configurations, a fully-constrained-status token that is used during training to enable classifier-free guidance during inference. Special tokens embedding layer 308 includes a learned embedding table (e.g., PyTorch learned table torch.nn. Embedding). Special tokens embedding layer 308 then encodes each sentinel token in sentinel tokens 302 to generate embedded sentinel tokens. The embedded sentinel tokens are then concatenated into a vector as embedded sentinel tokens 312.

Constraint generation application 132 processes input sketch 134 to generate constraint tokens 304 by tokenizing any constraint associated with input sketch 134. Each constraint token in constraint tokens 304 corresponds to a geometric relationship between geometric entities in input sketch 134. Special tokens embedding layer 308 encodes each constraint token in constraint tokens 304 to generate embedded constraint tokens. The embedded constraint tokens are then concatenated into a vector as embedded constraint tokens 314.

At step 914, constraint generation application 132 generates embedded geometry data 316 using embedded point data 418, embedded entity type tokens 420, embedded construction status tokens 422, and embedded locked status tokens 424. Constraint generation application 132 processes embedded point data 418, embedded entity type tokens 420, embedded construction status tokens 422, and embedded locked status tokens 424 to generate embedded geometry data 316 using token pooling transformer 426. Token pooling transformer 426 then applies one or more self-attention layers to exchange information between embedded point data 418, embedded entity type tokens 420, embedded construction status tokens 422, and embedded locked status tokens 424. Token pooling transformer 426 then provides the final hidden state of the pooling tokens as embedded geometry data 316.

At step 916, constraint generation model 318 concatenates embedded geometry data 316, embedded sentinel tokens 312, and embedded constraint tokens 314 to generate concatenated tokens. Constraint generation model 318 processes embedded sentinel tokens 312, embedded constraint tokens 314, and embedded geometry data 316 to generate concatenated tokens.

At step 918, a transformer processes the concatenated tokens to generate contextualized geometry and constraint embeddings. Encoder 320 is a bi-directional transformer that first processes the concatenated tokens to generate contextualized geometry and constraint embeddings 321 which includes final geometry, sentinel and constraint embeddings using a multi-head self-attention network. The multi-head self-attention network compares each embedded token of the concatenated tokens with every other embedded token of the concatenated tokens as respective token pairs to compute attention scores that quantify relational patterns among the embedded tokens of the concatenated tokens. In one example, the multi-head self-attention network uses a scaled dot-product followed by a Softmax function to generate normalized attention weights for each embedded token pair. Each head in the multi-head self-attention operation performs the computation independently, thereby extracting parallel relational patterns, such as alignment between arcs and points or shared parameters among closely related constraints. The output of each multi-head self-attention operation is aggregated and passed through feed-forward transformations, generating contextualized geometry and constraint embeddings 321. Encoder 320 provides the generated contextualized geometry and constraint embeddings 321 to gatherer 322.

At step 920, gatherer 322 converts input sketch constraints 317 using contextualized geometry and constraint embeddings 321. Gatherer 322 uses contextualized geometry and constraint embeddings 321 to convert each constraint in input sketch constraints 317 into a sequence of embeddings in gathered constraints 323. Each input sketch constraint 317 includes a constraint type and one or more geometric entity identifiers, which is converted into a sequence of embeddings in gathered constraints using corresponding embeddings from contextualized geometry and constraint embeddings 321.

At step 922, a transformer generates pointers 326. Decoder 324 is a causal transformer that receives gathered constraints 323, and next-token probability distributions 329 to generate pointers 326. At each decoding step, decoder 324 receives the gathered constraints 323 from a key-value memory. Decoder 324 performs masked self-attention to the concatenated autoregressive sequence, which includes the prompt, using a causal transformer so that each token attends only to earlier tokens and thereby preserves the order of the constraint sequence 330. The results of the masked self-attention pass through a linear projection layer to generate pointers 326.

At step 924, pointer network 328 processes pointers 326 and contextualized geometry and constraint embeddings 321 to generate a constraint token. Pointer network 328 determines a similarity between pointers 326 and contextualized geometry and constraint embeddings 321 (e.g., using a matrix multiplication or dot product) to produce logits, which are unnormalized real-valued numbers. Pointer network 328 then applies a Softmax function to the logits to produce next-token probability distribution 329. Constraint generation model 318 selects the token with the highest probability in the next-token probability distribution 329 to generate a constraint token.

At step 926, constraint generation model 318 determines whether end-of-sequence token <EOS> is generated. The autoregressive loop of decoder 324 and pointer network 328 continues until constraint generation model 318 generates the end-of-sequence token <EOS> in the next constraint token. If constraint generation model 318 generates the end-of-sequence token <EOS> (926—Yes), then the method 900 proceeds to step 928, where constraint generation model 318 generates a constraint sequence. Constraint generation model 318 appends the end-of-sequence token <EOS> to all previously generated constraint tokens to generate the constraint sequence. Constraint generation model 318 provides the generated constraint sequence including constraint sequence 330 to generated constraints 136. If constraint generation model 318 does not generate the end-of-sequence token <EOS> (926—NO), then the method 900 proceeds to step 922 to generate pointers using a transformer.

### Constraint Generation Model Training

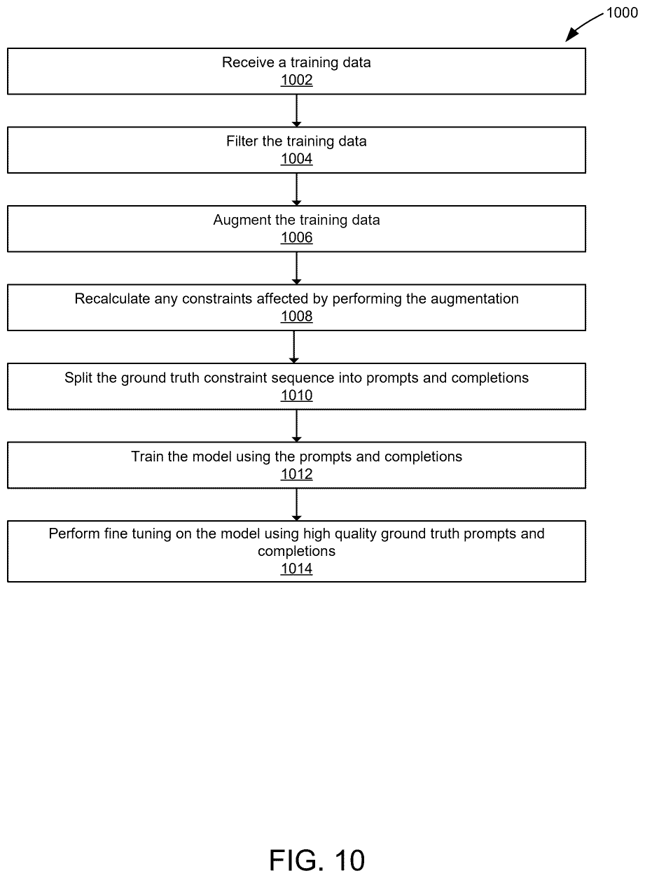

FIG. 10 is a flow diagram of method steps for supervised training and fine tuning of a constraint generation model, according to various embodiments. Although the method steps are described with reference to the embodiments of FIGS. 1-5, persons skilled in the art will understand that any system configured to implement the method steps, in any order, falls within the scope of the present disclosure.

Method 1000 begins at step 1002, where training data preparation module 504 receives training data 502. Training data 502 includes one or more training data elements, which are used to train constraint generation model 318. Training data 502 can be loaded from data store 122 or some other source. Each training data element includes an input sketch and a ground truth constraint sequence for the sketch. A sketch can be included in multiple training data elements when more than one ground truth constraint sequence is available for that sketch. In some cases, the ground truth constraint sequences are generated by human designers, a reference constraint generator, and/or the like.

At step 1004, training data preparation module 504 filters training data 502. Training data preparation module 504 filters the received training data 502 to ensure that there are a sufficient number of training data elements that include a sketch that is fully constrained. For example, the filtering ensures that at least 10% of the geometric entities in each sketch within the training data elements are fully constrained. Filtering training data 502 to include training data elements that have a higher percentage of fully constrained geometric entities improves convergence of constraint generation model 318 during training.

At step 1006, training data preparation module 504 augments training data 502. The objective of augmentation is to increase the number of training data elements in training data 502 while also increasing the geometric diversity of training data 502. Training data preparation module 504 performs one or more augmentation operations on selected training data examples in training data 502. The one or more augmentation operations perform at least one change to the geometry of the input sketch of a training data example and also make one or more corresponding changes in the ground truth constraint sequence so as to preserve the geometric correctness of the ground truth constraint sequence for the augmented training data element. Examples of the one or more augmentation operations include, without limitation, a rotation operation, a scale operation, a mirror operation, a translation operation to one or more of the geometric entities within a sketch of a training data example.

At step 1008, training data preparation module 504 recalculates any constraints affected by performing the augmentation. When training data preparation module 504 performs augmentation to the geometric entities, the corresponding constraints can alter and training data preparation module 504 recalculates those constraints accordingly.

At step 1010, variable length prompt generator 508 splits the ground truth constraint sequence into prompts and completions. Over multiple iterations, variable length prompt generator 508 receives a training data element selected by supervised training module 514 from the set of training data elements 506. Variable length prompt generator 508 then converts the selected training data element into a prompt 510 and a completion 512 constraint sequence. Variable length prompt generator 508 randomly partitions the ground truth constraint sequence into two sets of the constraints. A first set of the constraints is added to prompt 510 and a second set of the constraints is added to completion 512. Prompt 510 and completion 512 are concatenated and become the ground truth for the newly created training data example. Placing a portion of the constraints in the ground truth constraint sequence in prompt 510 provides further diversity in the training data and also provides a richer example of good constraints during training. Variable length prompt generator 508 partitions the ground truth constraint sequence so that anywhere from zero to eighty percent of the constraints in the ground truth constraint sequence are present in prompt 510. Variable length prompt generator 508 can generate multiple variable length prompts with different portions of the constraints in the ground truth constraint sequence can be generated to provide additional training data elements for use by supervised training module 514.

At step 1012, supervised training module 514 trains constraint generation model 318 using the prompts and completion. Supervised training module 514 iteratively trains constraint generation model 318 using the prompts and completion. In some examples, supervised training module 514 further adds a token to each prompt 510 to indicate whether the input sketch in the prompt 510 is fully constrained. Supervised training module 514 then presents the prompt 510 to constraint generation model 318. Constraint generation model 318 then autoregressively generates a constraint sequence (e.g., constraint sequence 330). Supervised training module 514 then compares the constraint sequence generated by constraint generation model 318 to the ground truth to determine a loss, such as a cross-entropy loss.

Supervised training module 514 then uses gradients of the cross-entropy loss to update constraint generation model 318 by backpropagation. Supervised training module 514 continues training constraint generation model 318 by using additional prompts 510 and completion 512, and using additional losses to update constraint generation model 318. The training continues until an exit criterion is met. In some examples, supervised training module 514 stops training when the training over k consecutive training epochs results in limited further improvement in the ability of constraint generation model 318 to generate constraint sequences. In some examples, supervised training module 514 stops training after a predetermined number of training epochs. Supervised training module 514 stores the updated constraint generation model 318 in data store 122 as trained model 124.

At step 1014, supervised training module 514 performs fine tuning on constraint generation model 318 using high quality ground truth prompts and completions. Supervised training module 514 receives high quality training data that includes a selected subset of fully constrained sketches that do not include redundant or conflicting constraints. High quality training data includes sketches with minimal degrees of freedom and/or stable sketches validated by a solver. In some examples high quality training data includes one or more user validated fully constraint sketches.

Supervised training module 514 provides each sketch in high quality training data to constraint generation model 318 using high quality ground truth prompts and completions to generate a constraint sequence (e.g., constraint sequence 330). Supervised training module 514 then compares the constraint sequence generated by constraint generation model 318 to the corresponding high quality ground truth constraint sequence for the sketch to determine a loss by using the cross-entropy loss.

Supervised training module 514 uses gradients of the cross-entropy loss to update constraint generation model 318 by backpropagation. Supervised training module 514 continues training by selecting new training data elements from high quality training data and using additional losses to update constraint generation model 318. The training continues until an exit criterion is met. In some examples, supervised training module 514 stops training when the training over k consecutive training epochs results in limited further improvement in the ability of constraint generation model 318 to generate constraint sequences. In some examples, supervised training module 514 stops training after a predetermined number of training epochs. In some embodiments, supervised training module 514 further stores the updated constraint generation model 318 in data store 122 as trained model 124.

### Constraint Generation Model Alignment Training

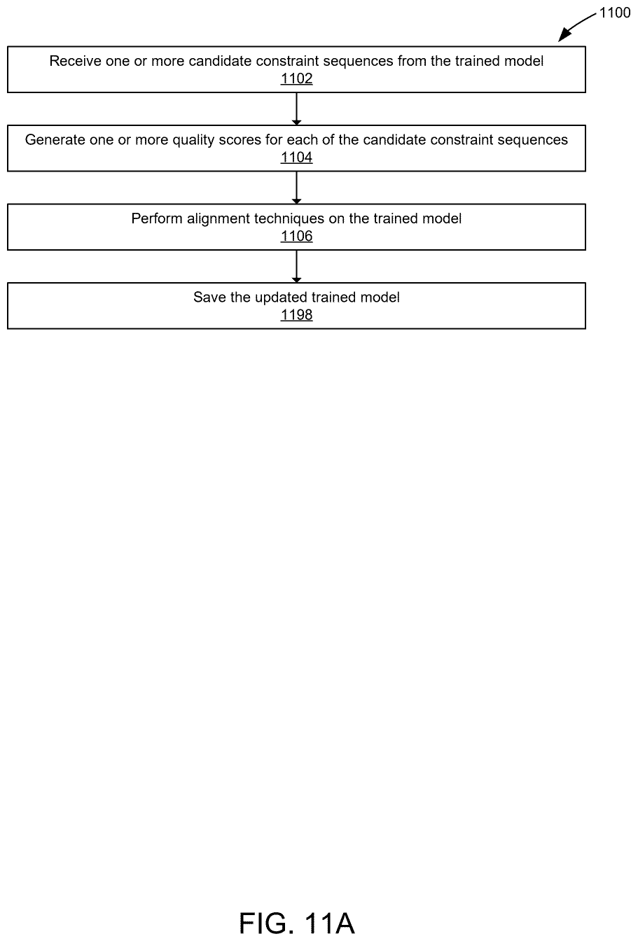

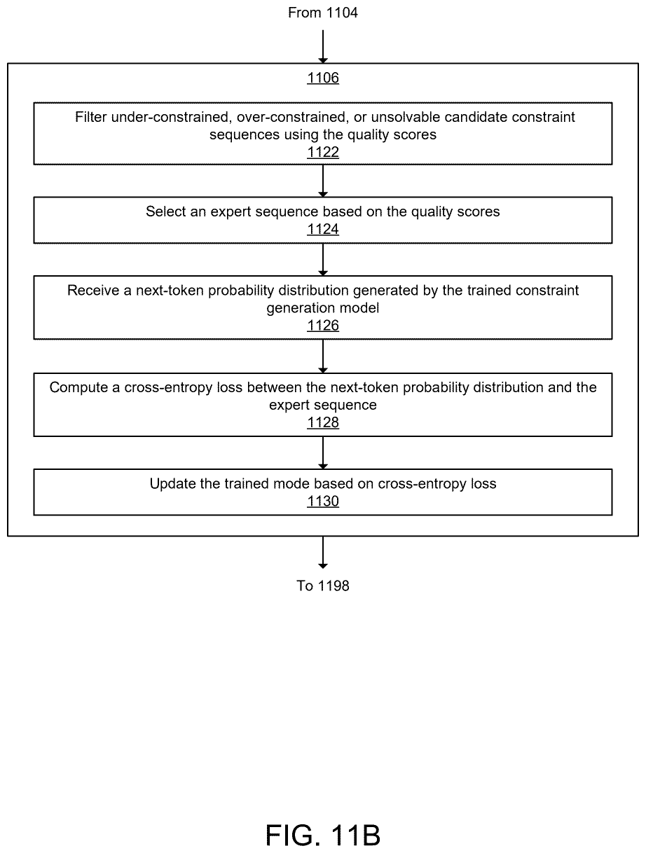

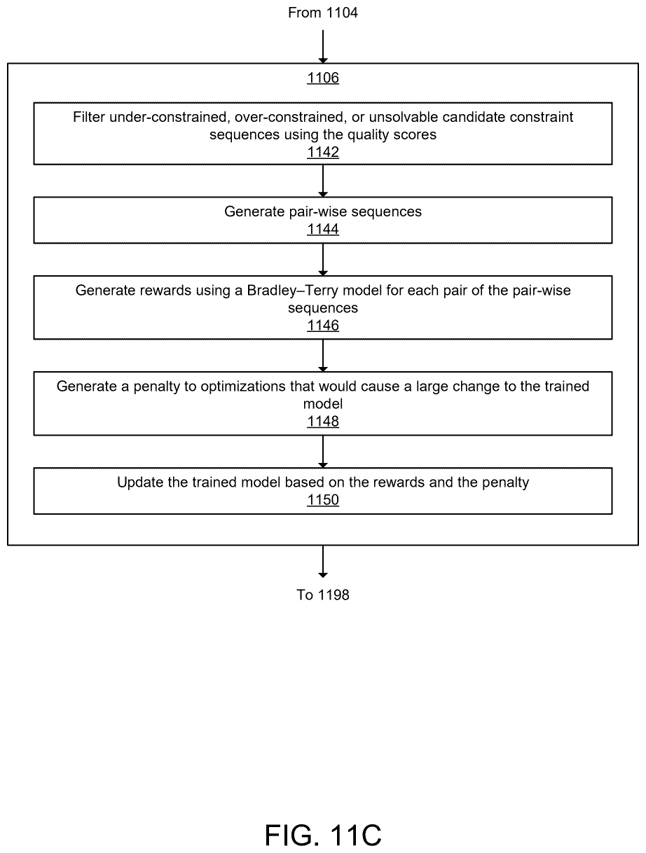

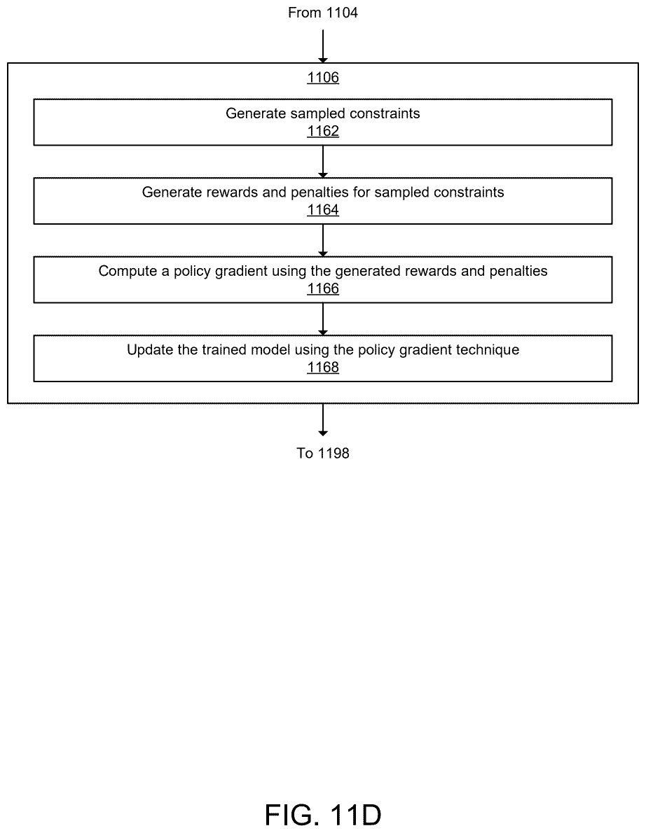

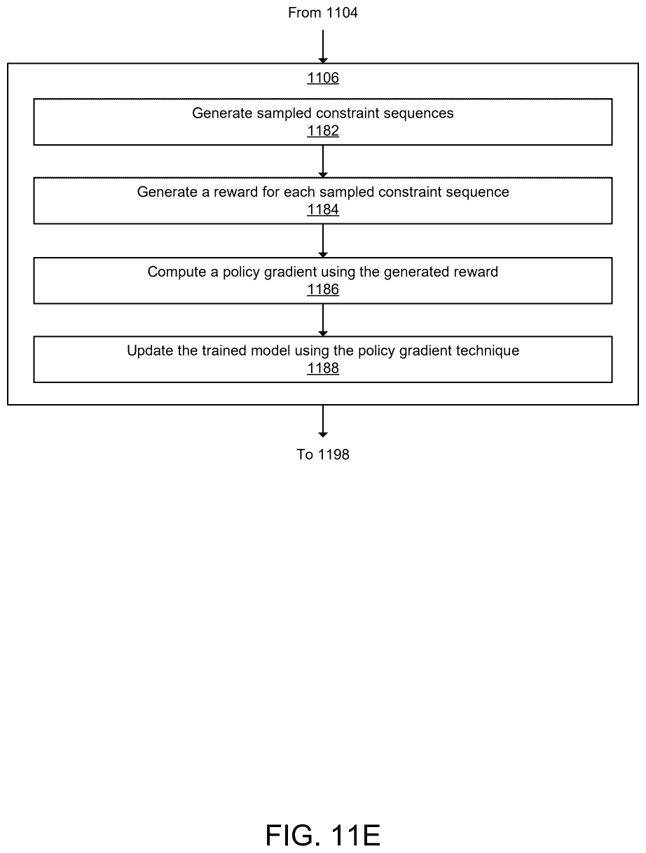

FIG. 11A is a flow diagram of method steps for performing different alignment training techniques on trained model 124, according to various embodiments. Although the method steps are described with reference to the embodiments of FIGS. 1-8, persons skilled in the art will understand that any system configured to implement the method steps, in any order, falls within the scope of the present disclosure.

Method 1100 begins at step 1102, where preference-based optimization module 116 or reinforcement learning module 118 receives one or more candidate constraint sequences from trained model 124. During preference-based optimization, preference-based optimization module 116 receives a plurality of candidate constraint sequences 604(i) each generated by trained model 124 including constraint generation model 318. During reinforcement learning, reinforcement learning module 118 receives candidate constraint sequence 604 from trained model 124 including constraint generation model 318.

Constraint generation model 318 receives an input sketch 602 during reinforcement learning or a plurality of input sketches as input sketches 602(i) during preference-based optimization. Each input sketch 602 can be loaded from data store 122 or some other source. Each input sketch 602 can include a partial set of constraints. Constraint generation model 318 receives each input sketch 602 and generates corresponding candidate constraint sequence 604.

At step 1104, scoring module 112 generates one or more quality scores for each of the candidate constraint sequences. Scoring module 112 uses each input sketch 602 and each corresponding candidate constraint sequence 604 to generate a sketch solution using constraint solver 606. Scoring module 112 then generates quality scores 612 using design intent score function 608 and stability score function 610 based on generated sketch solution. Quality scores 612 quantifies the stability and DOFs of the candidate constraint sequence 604.

At step 1106, preference-based optimization module 116 or reinforcement learning module 118 performs alignment techniques on trained model 124 and/or constraint generation model 318. preference-based optimization module 116 or reinforcement learning module 118 updates constraint generation model 318 during each iteration of alignment. The alignment techniques are described in further detail in FIGS. 11B-11E.

At step 1198, preference-based optimization module 116 or reinforcement learning module 118 saves the updated trained model including updated constraint generation model 318. Updated model using preference-based optimization module 116 or reinforcement learning module 118 can be stored as trained model 124 in data store 122.

FIG. 11B is a flow diagram illustrating method steps for expert iteration (ExIt) optimization at step 1106 of method 1100, according to various embodiments. Although the method steps are described with reference to the embodiments of FIGS. 1-7, persons skilled in the art will understand that any system configured to implement the method steps, in any order, falls within the scope of the present disclosure.

At step 1122, filter and sampler 702 filters under-constrained, over-constrained, or unsolvable candidate constraint sequences using quality scores 612. Filter and sampler 702 receives a plurality of candidate constraint sequences 604(i) generated by scoring module 112. Filter and sampler 702 first samples a specified number of constraint sequences for each input sketch 602 at a particular temperature parameter. Filter and sampler 702 then filters candidate constraint sequences 604(i) by removing any candidate constraint sequence 604 flagged as under-constrained, over-constrained, unsolvable, or otherwise not meeting predefined quality criteria based on corresponding quality scores 612. In some cases, filter and sampler 702 uses a sample count parameter and/or a temperature parameter to sample constraint sequences. The sample count parameter is a numeric quantity (e.g., 5, 10, or 128) that determines the size of generated expert sequence 704. The temperature parameter adjusts the probability distribution at each sampling step. For example, a temperature parameter of T=1 is considered standard or neutral temperature, but higher temperatures make the sampling probability more random.

At step 1124, filter and sampler 702 selects an expert sequence based on quality scores 612. Filter and sampler 702 samples a specified number of constraint sequences based on the sample count parameter and the temperature parameter to generate expert sequence 704. Expert sequence 704 includes a sequence that converges successfully and has low DOFs.

At step 1126, cross-entropy loss 706 receives next-token probability distributions 703 generated by the trained constraint generation model 318. Cross-entropy loss 706 performs cross entropy during expert iteration optimization. Cross-entropy loss 706 receives expert sequence 704, which represents high-quality constraint sequences having successfully converged and exhibiting minimal DOF. Cross-entropy loss 706 also receives next-token probability distribution 703 generated by pointer network 328 within constraint generation model 318.

At step 1128, cross-entropy loss 706 computes a cross-entropy loss between next-token probability distribution 703 and expert sequence 704. Cross-entropy loss 706 computes a cross-entropy loss value by comparing each token in expert sequence 704 against the next-token probability distributions 703 generated by constraint generation model 318. Cross-entropy loss 706 measures the negative log-likelihood of the expert sequence 704 given next-token probability distribution 703 by using the cross-entropy loss as indicated in Equation 1.

At step 1130, cross-entropy loss 706 updates constraint generation model 318 based on the cross-entropy loss. Cross-entropy loss 706 generates gradients from the cross entropy loss of step 1128 and then uses the cross entropy loss to update the parameters of the constraint generation model 318 using backpropagation.

Preference-based optimization module 116 iteratively repeats steps 1122 through 1130, wherein at each iteration the constraint generation model 318 generates candidate constraint sequences 604(i). The iterative process continues until an exit condition is met, such as reaching a specified maximum number of iterations or achieving minimal improvement between consecutive iterations.

FIG. 11C is a flow diagram illustrating method steps for DPO at step 1106 of method 1100, according to various embodiments. Although the method steps are described with reference to the embodiments of FIGS. 1-7, persons skilled in the art will understand that any system configured to implement the method steps, in any order, falls within the scope of the present disclosure.

At step 1142, filter and sampler 702 filters under-constrained, over-constrained, or unsolvable candidate constraint sequences using quality scores 612. Filter and sampler 702 receives a plurality of candidate constraint sequences 604(i) generated by scoring module 112.

Filter and sampler 702 first samples a specified number of constraint sequences for each input sketch 602 at a particular temperature parameter. Filter and sampler 702 then filters candidate constraint sequences 604(i) by removing any candidate constraint sequence 604 flagged as under-constrained, over-constrained, unsolvable, or otherwise not meeting predefined quality criteria based on corresponding quality scores 612. In some cases, filter and sampler 702 uses a sample count parameter and/or a temperature parameter to sample constraint sequences. The sample count parameter is a numeric quantity (e.g., 5, 10, or 128) that determines the size of generated pair-wise sequences 710. The temperature parameter adjusts the probability distribution at each sampling step. For example, a temperature parameter of T=1 is considered standard or neutral temperature, but higher temperatures make the sampling probability more random.

At step 1144, filter and sampler 702 generates pair-wise sequences 710. For direct preference optimization, filter and sampler 702 samples a specified number of constraint sequences based on the sample count parameter and the temperature parameter to generate pair-wise sequences 710. Pair-wise sequences 710 includes pairs of sequences that converge successfully and have low DOFs. Filter and sampler 702 designates one sequence in each pair as superior, indicating a higher fraction of fully constrained geometry relative to the other sequence based on constraint solver 606 feedback.

At step 1146, Bradley-Terry model 712 generates rewards using a Bradley-Terry model for each pair of pair-wise sequences 710. Bradley-Terry model 712 performs DPO using each pair of constraint sequences in the pair-wise sequences 710. Each pair of constraint sequences in pair-wise sequences 710 is compared based on how well each constraint sequence constrains the input sketch 602. The Bradley-Terry model 712 performs pairwise comparisons using a Bradley-Terry statistical model combined with a logistic-based ranking function to convert pairwise comparisons into reward signals. The Bradley-Terry model transforms each pairwise comparison into an implicit reward signal that favors the candidate constraint sequence in each pair that achieves a greater degree of full constraint. A logistic-based ranking function (e.g., a logistic sigmoid function) converts the output of the Bradley-Terry model into a continuous scale (e.g., range of real numbers between zero and one) as a reward. The reward is generated for each pair of constraint sequences in pair-wise sequences 710. The resulting rewards guide the model toward generating constraint sequences with higher rankings (e.g., higher proportions of fully constrained sketches).

At step 1148, Bradley-Terry model 712 generates a penalty to optimizations that would cause a large change to the trained model including constraint generation model 318. Bradley-Terry model 712 applies a penalty term to prevent large changes from being made to constraint generation model 318, unless such deviations result in more fully constrained sketches.

At step 1150, Bradley-Terry model 712 updates constraint generation model 318 based on the rewards and penalty. Bradley-Terry model 712 converts the reward and penalty into a preference-based loss that is differentiable with respect to the parameters of constraint generation model 318. Bradley Terry model 712 calculates gradients of the preference-based loss with respect to the parameters of constraint generation model 318. Bradley-Terry model 712 applies calculated gradients through backpropagation to update constraint generation model 318.

FIG. 11D is a flow diagram illustrating method steps for per constraint reinforcement learning at step 1106 of method 1100, according to various embodiments. Although the method steps are described with reference to the embodiments of FIGS. 1-8, persons skilled in the art will understand that any system configured to implement the method steps, in any order, falls within the scope of the present disclosure.

At step 1162, constraint filter and sampler 802 generates sampled constraints. Constraint filter and sampler 802 receives candidate constraint sequence 604 and associated quality scores 612 generated by scoring module 112. Constraint filter and sampler 802 evaluates candidate constraint sequence 604 using quality scores 612. Constraint filter and sampler 802 samples a specific number of constraints for each candidate constraint sequence 604 at a particular temperature parameter to generate sampled constraints. Constraint filter and sampler 802 then flags constraints within sampled constraints which are related to over constrained sketches, unsolvable sketches, unstable sketches, and other failures using quality scores 612. In some cases, constraint filter and sampler 802 uses a sample count parameter and/or a temperature parameter to sample constraints. The sample count parameter is a numeric quantity (e.g., 5, 10, or 128) that determines the size of generated sampled constraints. The temperature parameter adjusts the probability distribution at each sampling step. For example, a temperature parameter of T=1 is considered standard or neutral temperature, but higher temperatures make the sampling probability more random. Constraint filter and sampler 802 provides sampled constraints to a per constraint reward function 804 and a penalty function 806.

At step 1164, per constraint reward function 804 generates rewards and penalty function 806 generates penalties for sampled constraints. Per constraint reward function 804 receives sampled constraints from constraint filter and sampler 802. Per constraint reward function 804 generates a reward proportionally to the number of fully constrained geometric entities (e.g., a line with zero DOF) associated with each constraint in sampled constraints over all geometric entities. Rewards increase the overall desirability of rewarded constraints in the per-constraint reinforcement learning process, encouraging similar constraints in subsequent generations. Optionally, per constraint reward function 804 can generate an additional Kullback-Leibler (KL) penalty term to control excessive divergence.

Penalty function 806 receives sampled constraints from constraint filter and sampler 802. Penalty function 806 applies penalties to the sampled constraints which are flagged by constraint filter and sampler 802. The flagged sampled constraints include constraints within over constrained sketches, unsolvable sketches, unstable sketches, and other failures. Penalty function 806 applies penalties proportional to the severity of the flagged sampled constraints (e.g., highest penalty for the constraints within unstable sketches). Penalties reduce the overall desirability of the penalized constraints in the per-constraint reinforcement learning process, discouraging similar constraints in subsequent generations.

At step 1166, per constraint policy gradient module 808 computes a policy gradient using the generated rewards and penalties. Per constraint policy gradient module 808 receives rewards from per constraint reward function 804 and penalties from penalty function 806. Per constraint policy gradient module 808 computes an advantage term explicitly by subtracting the baseline (e.g., moving average of past net rewards) from the net reward, which is the reward minus penalty, generated for each constraint in sampled constraints. Per constraint policy gradient module 808 uses policy gradient techniques to adjust the parameters of constraint generation model 318 in the direction that maximizes expected future rewards. Policy gradient techniques include, but not limited to ReMax, REINFORCE-Leave-One-Out (RLOO), Group Relative Policy Optimization (GRPO), and/or the like. By weighting parameter updates according to advantages. The advantage term directly scales the gradient of the log-probability of selecting each constraint, enabling reinforcement of constraints that outperform the baseline and discouragement of constraints underperforming the baseline.

At step 1168, per constraint policy gradient module 808 updates constraint generation model 318 using the policy gradient technique. Per constraint policy gradient module 808 utilizes rewards from per constraint reward function 804 and penalties from penalty function 806 to update constraint generation model 318.

FIG. 11E is a flow diagram illustrating method steps for per sequence reinforcement learning at step 1106 of method 1100, according to various embodiments. Although the method steps are described with reference to the embodiments of FIGS. 1-8, persons skilled in the art will understand that any system configured to implement the method steps, in any order, falls within the scope of the present disclosure.

At step 1182, sequence filter and sampler 812 generates sampled constraint sequences. Sequence filter and sampler 812 receives candidate constraint sequence 604 and associated quality scores 612. Sequence filter and sampler 812 identifies constraints within candidate constraint sequence 604 that are related to fully constrained sketches with zero DOF or partially constrained sketches with non-zero DOFs using quality scores 612 at each reinforcement iteration. Sequence filter and sampler 812 removes constraints within candidate constraint sequence 604 that are not needed to fully constrain input sketch 602 (e.g., unneeded constraints) to generate a first truncated constraint sequence. Sequence filter and sampler 812 then generates multiple constraint sequences based on the first truncated constraint sequence as well as two additional constraint sequences corresponding to the portions of candidate constraint sequence 604 before and after the removed constraint. Sequence filter and sampler 812 generates additional truncated constraint sequences based on other constraints that are removed. Alternatively, sequence filter and sampler 812 can mask out unneeded constraints to generate truncated constraint sequences without removing constraints. Sequence filter and sampler 812 then samples a specific number of truncated constraint sequences at a particular temperature parameter to generate sampled constraint sequences. In some cases, sequence filter and sampler 812 use a sample count parameter and/or a temperature parameter to sample constraint sequences. The sample count parameter is a numeric quantity (e.g., 5, 10, or 128) that determines the size of generated sampled constraint sequences. The temperature parameter adjusts the probability distribution at each sampling step. For example, a temperature parameter of T=1 is considered standard or neutral temperature, but higher temperatures make the sampling probability more random.

At step 1184, per sequence reward function 814 generates a reward for each sampled constraint sequence. Per sequence reward function 814 receives sampled constraint sequences from sequence filter and sampler 812 with corresponding quality scores 612. Per sequence reward function 814 measures the fraction of fully constrained constraint sequences in sampled constraint sequences. Next, per sequence reward function 814 generates rewards proportionally to the fraction of fully constrained constraint sequences in sampled constraint sequences using quality scores 612 generated by scoring module 112. Rewards increase the overall desirability of rewarded constraint sequences in the per-sequence reinforcement learning process, encouraging similar constraint sequences in subsequent generations. Optionally, per sequence reward function 814 can generate an additional Kullback-Leibler (KL) penalty term to control excessive divergence. Per sequence reward function 814 provides rewards to the per sequence policy gradient module 816.

At step 1186, per sequence policy gradient module 816 computes a policy gradient using the generated reward. Per sequence policy gradient module 816 receives rewards from per sequence reward function 814. Per sequence policy gradient module 816 computes an advantage term explicitly by subtracting the baseline (e.g., moving average of past net rewards) from the rewards generated for each constraint sequence in sampled constraint sequences. Per sequence policy gradient module 816 uses policy gradient techniques to adjust the parameters of constraint generation model 318 in the direction that maximizes expected future rewards. Policy gradient techniques include, but not limited to ReMax, RLOO, GRPO, and/or the like. By weighting parameter updates according to advantages. The advantage term directly scales the gradient of the log-probability of selecting each constraint sequence, enabling reinforcement of constraints that outperform the baseline and discouragement of constraint sequences underperforming the baseline.

At step 1188, per sequence policy gradient module 816 updates constraint generation model 318 using the policy gradient technique. Per sequence policy gradient module 816 utilizes rewards from per sequence reward function 814, to update constraint generation model 318.

In sum, techniques are disclosed for generating constraints for CAD sketches using a machine learning model. The machine learning model includes a tokenization and embedding-based architecture. In some embodiments, each geometric entity such as a point, line, or arc is represented by a pooled embedding generated by collecting multiple sampled coordinates along the curve, passing the coordinates through a multi-layer perceptron (MLP), and combining the resulting geometry embedding with embeddings for entity type, construction flags, and locked/fixed status. A learned embedding is applied for each special token, including sentinel tokens (start/end of sequence, end of prompt, and pad) as well as constraint tokens (e.g., parallel, perpendicular, or linear dimension). The special-token embeddings and entity embeddings are concatenated to form an input sequence for a bi-directional transformer referred to as the encoder. The encoder processes the token sequence, generating contextualized representations for all geometry data and special tokens. Finally, a transformer decoder equipped with a pointer network references the encoder outputs to generate a constraint sequence, dynamically pointing to geometry data.

The machine learning model with the tokenization and embedding-based architecture is trained using a training pipeline based on training data including partial or fully constrained sketches. In some embodiments, the training pipeline performs data augmentation, applying geometric transformations such as rotation, zoom, flip, or shift to input sketches and then recalculating constraints (e.g., flipping a horizontal alignment into a vertical one). Furthermore, classifier-free guidance (CFG) is employed to bias the machine learning model toward generating fully constrained sketches whose geometric primitives have zero or minimal degrees of freedom. During training, a variable length prompt is generated that includes a random subset of ground-truth constraints as input, and the machine learning model is trained to generate the rest of the constraints. Following an initial supervised training, a subsequent fine-tuning trains the machine learning model using fully constrained sketches.

Techniques are also disclosed for evaluating and scoring candidate constraint sequences generated by the machine learning model and iteratively updating the machine learning model through alignment techniques including preference-optimization and/or reinforcement learning. In some embodiments, a scoring module receives sketches including candidate constraint sequences from the machine learning model with the tokenization and embedding-based architecture which is trained using a training pipeline and generates quality scores via metrics such as remaining degrees of freedom (DOFs), convergence status, geometric stability, a regularity score, and/or constraints-to-dimensions ratio. In some embodiments, a preference optimization technique is applied to the machine learning model. In some cases, the preference optimization technique includes using expert iteration (ExIt). ExIt uses the quality scores to filter out under-constrained, over-constrained, or unsolvable constraint sequences or rank multiple constraint sequences to generate expert sequences. ExIt then updates the machine learning model with a cross-entropy loss. In some cases, the preference optimization technique includes direct preference optimization (DPO). DPO forms ranked pairs of constraint sequences, rewards each pair with the Bradley-Terry model while penalizing optimizations that would cause large changes to the machine learning model, and updates the machine learning model using the rewards and penalties. In some embodiments, reinforcement learning is applied to the machine learning model. The reinforcement-learning samples constraints generated by the machine learning model, assigns a reward (e.g., fully constrained or low degrees of freedom) and penalties (e.g., contradictory constraints), or samples generated sequence of constraints from machine learning model, assigns a reward. The reinforcement learning then uses the rewards and/or penalties to generate a policy-gradient used to update the machine learning model.

One technical advantage of the disclosed techniques relative to prior art is that the disclosed techniques more effectively capture complex geometric features and relationships of CAD sketches. The disclosed techniques also generate constraint sequences that are more accurate and more likely to converge and are more likely to result in fewer under-constrained, over-constrained, or contradictory constraints than constraint sequences generated by prior art techniques. The disclosed techniques further accelerate training convergence so that a constraint generation model can be trained using fewer training epochs and reduced computational resources. The disclosed techniques additionally support continual improvement to the constraint generation model. These technical advantages provide one or more technological advancements over prior art approaches.

Aspects of the subject matter described herein are set out in the following numbered clauses.

1. In some embodiments, a computer-implemented method for training a constraint generation model comprises receiving training data comprising a plurality of training data elements, each training data element comprising an input sketch and a ground truth constraint sequence, selecting a first training data element from the plurality of training data elements, generating a variable length prompt from the first training data element, presenting the variable length prompt to a constraint generation model to generate a first constraint sequence, generating a loss based on the first constraint sequence, and updating the constraint generation model based on the loss.

2. The computer-implemented method of clause 1, wherein generating the variable length prompt comprises partitioning the ground truth constraint sequence of the first training data element into a first set of constraints and a second set of constraints, and including the first set of constraints in the variable length prompt.

3. The computer-implemented method of clauses 1 or 2, wherein generating the loss comprises comparing the first constraint sequence and a ground truth including the variable length prompt and the second set of constraints.

4. The computer-implemented method of any of clauses 1-3, further comprising generating a second variable length prompt from the first training data element, presenting the second variable length prompt to the constraint generation model to generate a second constraint sequence, generating a second loss based on the second constraint sequence, and updating the constraint generation model based on the second loss.

5. The computer-implemented method of any of clauses 1-4, wherein the loss is a cross-entropy loss.

6. The computer-implemented method of any of clauses 1-5, further comprising filtering the training data so that each sketch in the training data include a minimum percentage of fully-constrained geometric entities.

7. The computer-implemented method of any of clauses 1-6, further comprising augmenting at least a second training data element of the training data by performing one or more augmentation operations on the input sketch of the second training data element.

8. The computer-implemented method of any of clauses 1-7, wherein the one or more augmentation operations include at least one of a rotation operation, a scale operation, a mirror operation, or a translation operation.

9. The computer-implemented method of any of clauses 1-8, wherein the one more augmentation operations are performed on a portion of geometric entities in the input sketch of the second training data element.

10. The computer-implemented method of any of clauses 1-9, wherein augmenting the first training data element comprises updating one or more constraints in the ground truth constraint sequence of the second training data element based on the one or more augmentation operations.

11. The computer-implemented method of any of clauses 1-10, wherein generating the variable length prompt comprises including a fully-constrained status token to the variable length prompt, the fully-constrained status token indicating whether the input sketch of the first training data element is fully constrained.

12. The computer-implemented method of any of clauses 1-11, further comprising further training the constraint generation model using high-quality training data, the high-quality training data comprising a plurality of training data elements that are fully-constrained.

13. In some embodiments, one or more non-transitory computer readable media store instructions that, when executed by one or more processors, cause the one or more processors to train a constraint generation model by performing the operations of receiving training data comprising a plurality of training data elements, each training data element comprising an input sketch and a ground truth constraint sequence, selecting a first training data element from the plurality of training data elements, generating a variable length prompt from the first training data element, presenting the variable length prompt to a constraint generation model to generate a first constraint sequence, generating a loss based on the first constraint sequence, and updating the constraint generation model based on the loss.

14. The one or more non-transitory computer readable media of clause 13, wherein generating the variable length prompt comprises partitioning the ground truth constraint sequence of the first training data element into a first set of constraints and a second set of constraints, and including the first set of constraints in the variable length prompt, and generating the loss comprises comparing the first constraint sequence and the second set of constraints.

15. The one or more non-transitory computer readable media of clauses 13 or 14, wherein the operations further comprise filtering the training data so that each sketch in the training data include a minimum percentage of fully-constrained geometric entities.

16. The one or more non-transitory computer readable media of any of clauses 13-15, wherein the operations further comprise augmenting at least a second training data element of the training data by performing one or more augmentation operations on the input sketch of the second training data element, wherein the one or more augmentation operations include at least one of a rotation operation, a scale operation, a mirror operation, or a translation operation.

17. The one or more non-transitory computer readable media of any of clauses 13-16, wherein augmenting the first training data element comprises updating one or more constraints in the ground truth constraint sequence of the second training data element based on the one or more augmentation operations.

18. The one or more non-transitory computer readable media of any of clauses 13-17, wherein generating the variable length prompt comprises including a fully-constrained status token to the variable length prompt, the fully-constrained status token indicating whether the input sketch of the first training data element is fully constrained.

19. The one or more non-transitory computer readable media of any of clauses 13-18, wherein the operations further comprise further training the constraint generation model using high-quality training data, the high-quality training data comprising a plurality of training data elements having fully-constrained sketches.

20. In some embodiments, a computer system comprises one or more memories that include instructions, and one or more processors that are coupled to the one or more memories and, when executing the instructions, are configured to train a constraint generation model by receiving training data comprising a plurality of training data elements, each training data element comprising an input sketch and a ground truth constraint sequence, selecting a first training data element from the plurality of training data elements, generating a variable length prompt from the first training data element, presenting the variable length prompt to a constraint generation model to generate a first constraint sequence, generating a loss based on the first constraint sequence, and updating the constraint generation model based on the loss.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The invention has been described above with reference to specific embodiments. Persons of ordinary skill in the art, however, will understand that various modifications and changes may be made thereto without departing from the broader spirit and scope of the invention as set forth in the appended claims. For example, and without limitation, although many of the descriptions herein refer to specific types of I/O devices that may acquire data associated with an object of interest, persons skilled in the art will appreciate that the systems and techniques described herein are applicable to other types of I/O devices. The foregoing description and drawings are, accordingly, to be regarded in an illustrative rather than a restrictive sense.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for training a constraint generation model, the method comprising:
receiving training data comprising a plurality of training data elements, each training data element comprising an input sketch and a ground truth constraint sequence;
selecting a first training data element from the plurality of training data elements;
generating a variable length prompt from the first training data element;
presenting the variable length prompt to a constraint generation model to generate a first constraint sequence;
generating a loss based on the first constraint sequence; and
updating the constraint generation model based on the loss.

2. The computer-implemented method of claim 1, wherein generating the variable length prompt comprises:
partitioning the ground truth constraint sequence of the first training data element into a first set of constraints and a second set of constraints; and
including the first set of constraints in the variable length prompt.

3. The computer-implemented method of claim 2, wherein generating the loss comprises comparing the first constraint sequence and a ground truth including the variable length prompt and the second set of constraints.

4. The computer-implemented method of claim 1, further comprising:
generating a second variable length prompt from the first training data element;
presenting the second variable length prompt to the constraint generation model to generate a second constraint sequence;
generating a second loss based on the second constraint sequence; and
updating the constraint generation model based on the second loss.

5. The computer-implemented method of claim 1, wherein the loss is a cross-entropy loss.

6. The computer-implemented method of claim 1, further comprising filtering the training data so that each sketch in the training data include a minimum percentage of fully-constrained geometric entities.

7. The computer-implemented method of claim 1, further comprising augmenting at least a second training data element of the training data by performing one or more augmentation operations on the input sketch of the second training data element.

8. The computer-implemented method of claim 7, wherein the one or more augmentation operations include at least one of a rotation operation, a scale operation, a mirror operation, or a translation operation.

9. The computer-implemented method of claim 7, wherein the one more augmentation operations are performed on a portion of geometric entities in the input sketch of the second training data element.

10. The computer-implemented method of claim 7, wherein augmenting the first training data element comprises updating one or more constraints in the ground truth constraint sequence of the second training data element based on the one or more augmentation operations.

11. The computer-implemented method of claim 1, wherein generating the variable length prompt comprises including a fully-constrained status token to the variable length prompt, the fully-constrained status token indicating whether the input sketch of the first training data element is fully constrained.

12. The computer-implemented method of claim 1, further comprising further training the constraint generation model using high-quality training data, the high-quality training data comprising a plurality of training data elements that are fully-constrained.

13. One or more non-transitory computer readable media storing instructions that, when executed by one or more processors, cause the one or more processors to train a constraint generation model by performing the operations of:
receiving training data comprising a plurality of training data elements, each training data element comprising an input sketch and a ground truth constraint sequence;
selecting a first training data element from the plurality of training data elements;
generating a variable length prompt from the first training data element;
presenting the variable length prompt to a constraint generation model to generate a first constraint sequence;
generating a loss based on the first constraint sequence; and
updating the constraint generation model based on the loss.

14. The one or more non-transitory computer readable media of claim 13, wherein:
generating the variable length prompt comprises:
partitioning the ground truth constraint sequence of the first training data element into a first set of constraints and a second set of constraints; and
including the first set of constraints in the variable length prompt; and
generating the loss comprises comparing the first constraint sequence and the second set of constraints.

15. The one or more non-transitory computer readable media of claim 13, wherein the operations further comprise filtering the training data so that each sketch in the training data include a minimum percentage of fully-constrained geometric entities.

16. The one or more non-transitory computer readable media of claim 13, wherein the operations further comprise augmenting at least a second training data element of the training data by performing one or more augmentation operations on the input sketch of the second training data element, wherein the one or more augmentation operations include at least one of a rotation operation, a scale operation, a mirror operation, or a translation operation.

17. The one or more non-transitory computer readable media of claim 16, wherein augmenting the first training data element comprises updating one or more constraints in the ground truth constraint sequence of the second training data element based on the one or more augmentation operations.

18. The one or more non-transitory computer readable media of claim 13, wherein generating the variable length prompt comprises including a fully-constrained status token to the variable length prompt, the fully-constrained status token indicating whether the input sketch of the first training data element is fully constrained.

19. The one or more non-transitory computer readable media of claim 13, wherein the operations further comprise further training the constraint generation model using high-quality training data, the high-quality training data comprising a plurality of training data elements having fully-constrained sketches.

20. A computer system, comprising:
one or more memories that include instructions; and
one or more processors that are coupled to the one or more memories and, when executing the instructions, are configured to train a constraint generation model by:
receiving training data comprising a plurality of training data elements, each training data element comprising an input sketch and a ground truth constraint sequence;
selecting a first training data element from the plurality of training data elements;
generating a variable length prompt from the first training data element;
presenting the variable length prompt to a constraint generation model to generate a first constraint sequence;
generating a loss based on the first constraint sequence; and
updating the constraint generation model based on the loss.
